(19) United States
(12) Patent Application Publication
(10) Pub. No.: US 2026/0150259 A1
(43) Pub. Date: May 28, 2026

(54) SEMICONDUCTOR DEVICE

(71) Applicant: SAMSUNG ELECTRONICS CO., LTD., Suwon-si (KR)

(72) Inventors: SUNGIL PARK, Suwon-si (KR); DAEWON HA, Suwon-si (KR); JAE HYUN PARK, Suwon-si (KR)

(73) Assignee: SAMSUNG ELECTRONICS CO., LTD., Suwon-si (KR)

(21) Appl. No.: 19/265,521

(22) Filed: Jul. 10, 2025

(30) Foreign Application Priority Data
Nov. 25, 2024 (KR) 10-2024-0169731
Dec. 27, 2024 (KR) 10-2024-0199314

(51) Int. Cl. H10B 10/00

(52) U.S. Cl. CPC H10B 10/125

(57) ABSTRACT

A semiconductor device includes: a first layer; and a second layer on the first layer, wherein the first layer includes: a first channel pattern; a second channel pattern on the first channel pattern; a first gate structure at least partially surrounding the first channel pattern and the second channel pattern; first source/drain patterns on opposite sides of the first channel pattern; and second source/drain patterns on opposite sides of the second channel pattern, wherein the first source/drain patterns are doped with an impurity of a first conductivity type, and the second source/drain patterns are doped with an impurity of a second conductivity type, wherein the second layer includes a static random-access memory (SRAM) device, wherein transistors of the SRAM device are each a p-type metal-oxide-semiconductor (PMOS) transistor or each an n-type metal-oxide-semiconductor (NMOS) transistor, and wherein a channel of the SRAM device includes IGZO or a two-dimensional material.

### CROSS-REFERENCE TO RELATED APPLICATIONS

This application claims priority to Korean Patent Application No. 10-2024-0169731, filed in the Korean Intellectual Property Office on Nov. 25, 2024, and Korean Patent Application No. 10-2024-0199314, filed in the Korean Intellectual Property Office on Dec. 27, 2024, the disclosures of which are incorporated herein by reference in their entireties.

### BACKGROUND

### 1. Field

Some embodiments of present disclosure relate to a semiconductor device.

### 2. Brief Description of Background Art

A semiconductor is a type of material between a conductor and an insulator, and means a material that conducts electricity under predetermined conditions. Various semiconductor devices can be manufactured by using a semiconductor material, and for example, a memory device and the like may be manufactured. These semiconductor devices may be used in various electronic devices.

As the electronics industry continues to advance, there is a growing demand for specific characteristics of the semiconductor devices. For example, there is an increasing demand for high reliability, high speed, and/or multifunctionality of the semiconductor devices. In order to meet these demands, structures in a semiconductor device are becoming increasingly complex and integrated.

### SUMMARY

According to some embodiments of the present disclosure, a semiconductor device with improved reliability and integration may be provided.

According to some embodiments of the present disclosure, a semiconductor device may include: a first layer; and a second layer on the first layer, wherein the first layer includes: a first channel pattern; a second channel pattern on the first channel pattern; a first gate structure at least partially surrounding the first channel pattern and the second channel pattern; first source/drain patterns on opposite sides of the first channel pattern; and second source/drain patterns on opposite sides of the second channel pattern, wherein the first source/drain patterns are doped with an impurity of a first conductivity type, and the second source/drain patterns are doped with an impurity of a second conductivity type different from the first conductivity type, wherein the second layer includes a static random-access memory (SRAM) device, wherein transistors of the SRAM device are each a p-type metal-oxide-semiconductor (PMOS) transistor or each an n-type metal-oxide-semiconductor (NMOS) transistor, and wherein a channel of the SRAM device includes IGZO or a two-dimensional material.

According to some embodiments of the present disclosure, a semiconductor device may include: a first layer; and a second layer on the first layer, wherein the first layer includes: a first channel pattern; a second channel pattern on the first channel pattern; a gate structure at least partially surrounding the first channel pattern and the second channel pattern; first source/drain patterns on opposite sides of the first channel pattern; and second source/drain patterns on opposite sides of the second channel pattern, wherein the first source/drain patterns are doped with an impurity of a first conductivity type, and the second source/drain patterns are doped with an impurity of a second conductivity type different from the first conductivity type, wherein the second layer includes a first pull-up transistor, a first pull-down transistor, a second pull-up transistor, a second pull-down transistor, a first pass transistor, and a second pass transistor, wherein gate electrodes of the first pull-up transistor, the first pull-down transistor, the second pull-up transistor, and the second pull-down transistor are connected together, and wherein channels of the first pull-up transistor, the first pull-down transistor, the second pull-up transistor, the second pull-down transistor, the first pass transistor, and the second pass transistor include IGZO or a two-dimensional material.

According to some embodiments of the present disclosure, a semiconductor device may include: a first layer; and a second layer on the first layer, wherein the first layer includes: a first channel pattern; a second channel pattern on the first channel pattern; a gate structure at least partially surrounding the first channel pattern and the second channel pattern; first source/drain patterns on opposite sides of the first channel pattern; second source/drain patterns on opposite sides of the second channel pattern, wherein the first source/drain patterns are doped with an impurity of a first conductivity type, and the second source/drain patterns are doped with an impurity of a second conductivity type different from the first conductivity type, wherein the second layer includes a first pull-up transistor, a first pull-down transistor, a second pull-up transistor, a second pull-down transistor, a first pass transistor, and a second pass transistor, and wherein a gate electrode of the first pull-up transistor, a gate electrode of the first pull-down transistor, a gate electrode of the second pull-up transistor, and a gate electrode of the second pull-down transistor are connected together.

According to some embodiments of the present disclosure, a method of manufacturing a semiconductor device may include: forming a first layer of the semiconductor device; and forming a second layer of the semiconductor device on the first layer, wherein the first layer includes: a first channel pattern; a second channel pattern on the first channel pattern; a first gate structure at least partially surrounding the first channel pattern and the second channel pattern; first source/drain patterns on opposite sides of the first channel pattern; and second source/drain patterns on opposite sides of the second channel pattern, wherein the first source/drain patterns are doped with an impurity of a first conductivity type, and the second source/drain patterns are doped with an impurity of a second conductivity type different from the first conductivity type, wherein the second layer includes a static random-access memory (SRAM) device, wherein a plurality of transistors of the SRAM device are each a p-type metal-oxide-semiconductor (PMOS) transistor or each an n-type metal-oxide-semiconductor (NMOS) transistor, and wherein a channel of the SRAM device includes IGZO or a two-dimensional material.

According to some embodiments of the present disclosure, the second layer includes: a third channel pattern; a second gate structure at least partially surrounding the third channel pattern; and third source/drain patterns on opposite sides of the third channel pattern.

According to some embodiments of the present disclosure, the second layer further includes: a fourth channel pattern on the third channel pattern; a third gate structure at least partially surrounding the fourth channel pattern; and fourth source/drain patterns on opposite sides of the fourth channel pattern, wherein at least one of the third source/drain patterns and at least one of the fourth source/drain patterns are connected.

According to some embodiments of the present disclosure, the reliability and integration of semiconductor devices may be improved.

### BRIEF DESCRIPTION OF DRAWINGS

FIG. 1 schematically illustrates a structure of a semiconductor device according to an embodiment.

FIG. 2 illustrates an arrangement of a first layer and a second layer in a semiconductor device according to an embodiment.

FIG. 3 illustrates a circuit diagram for explaining a static random-access memory (SRAM) cell of a semiconductor device according to an embodiment.

FIG. 4 illustrates a cross-sectional view of a semiconductor device according to an embodiment.

FIG. 5 illustrates a top plan view of a first layer of a semiconductor device according to an embodiment.

FIG. 6 illustrates a top plan view of a first portion of a second layer of a semiconductor device according to an embodiment.

FIG. 7 illustrates a top plan view of a second portion of a second layer of a semiconductor device according to an embodiment.

FIG. 8 illustrates a cross-sectional view taken along a line III-III′ of FIG. 6.

FIG. 9 illustrates a cross-sectional view taken along a line IV-IV′ of FIG. 6 and FIG. 7.

FIG. 10 illustrates a planar layout of a second layer according to an embodiment.

FIG. 11 illustrates a cross-sectional view taken along a line IIA-IIA′ of FIG. 10.

FIG. 12 to FIG. 58 illustrate cross-sectional views of a manufacturing process of a semiconductor device according to an embodiment.

### DETAILED DESCRIPTION

Non-limiting example embodiments of the present disclosure will be described more fully hereinafter with reference to the accompanying drawings, in which example embodiments of the present disclosure are shown. As those skilled in the art would realize, the described example embodiments may be modified in various different ways, all without departing from the spirit or scope of the present disclosure.

In the drawings, the thicknesses of layers, films, panels, regions, areas, etc., may be exaggerated for clarity. Like reference numerals designate like elements throughout the specification. It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present.

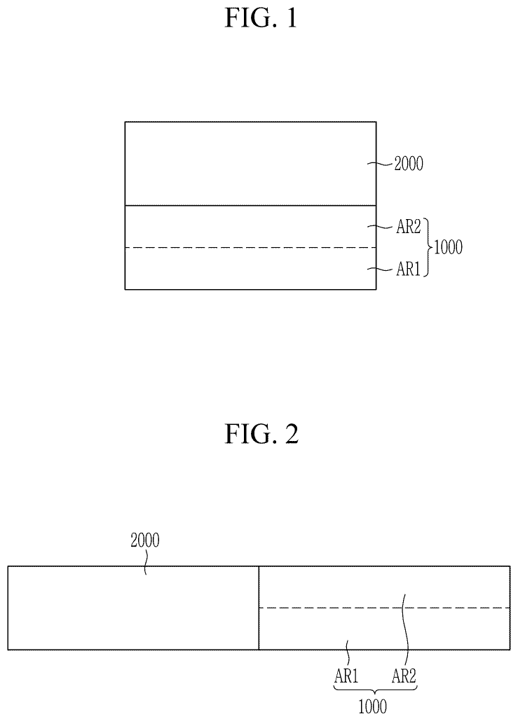

Hereinafter, a semiconductor device according to an embodiment of the present disclosure will be described. FIG. 1 schematically illustrates a structure of a semiconductor device according to an embodiment. Referring to FIG. 1, a semiconductor device according to the present embodiment may have a structure in which a first layer 1000 and a second layer 2000 are vertically stacked. In this case, the first layer 1000 may include a first active region AR1 and a second active region AR2, which are sequentially stacked. One from among the first active region AR1 and the second active region AR2 may be a p-type metal-oxide-semiconductor field-effect transistor (PMOSFET) region, and the other from among the first active region AR1 and the second active region AR2 may be an n-type metal-oxide-semiconductor field-effect transistor (NMOSFET) region. In addition, the second layer 2000 may include a static random-access memory (SRAM) device. Embodiments of the present disclosure may include vertically stacking PMOS, NMOS, and SRAM to reduce the area occupied by the semiconductor device.

FIG. 2 illustrates an arrangement of the first layer 1000 and the second layer 2000 in a semiconductor device according to an embodiment. Referring to FIG. 2, the first layer 1000 including the first active region AR1 and the second active region AR2 and the second layer 2000 including the SRAM may be disposed side by side with respect to each other. In this case, the planar area occupied by the device increases compared to FIG. 1.

However, embodiments of the present disclosure may reduce the area of the device by vertically stacking the first layer 1000 including PMOS and NMOS and the second layer 2000 including SRAM devices.

In this case, the channel of the SRAM device may include IGZO or a two-dimensional material. The two-dimensional material may include, for example, at least one from among molybdenum disulfide (MoS₂), molybdenum diselenide (MoSe₂), tungsten disulfide (WS₂), tungsten diselenide (WSe₂), and black phosphorus (BP), but is not limited thereto. This will be described separately later, but when the second layer 2000 including SRAM is formed after the first layer 1000 including PMOS and NMOS is formed, the first layer 1000 already formed may be damaged by the process of forming the second layer 2000. Particularly, when silicon is used as a channel material in the process of forming the second layer 2000, the first layer 1000 disposed below may be affected by the high temperature process. In the present embodiment, the channel material of the second layer 2000 may include IGZO or a two-dimensional material. Since the process of forming such a material does not use a high temperature compared to a silicon channel forming process, damage to the first layer 1000 may be prevented when forming the second layer 2000.

In the semiconductor device according to the present embodiment, the SRAM may be made of only PMOS or NMOS. That is, a single SRAM device may not include both PMOS and NMOS, but may include only NMOS or only PMOS. This is due to the characteristics of IGZO or a two-dimensional material used as a channel of the SRAM device in embodiments of the present disclosure. Particularly, when IGZO is included as a channel material, the operation characteristics may be poor when forming a PMOS, so the single SRAM device may be formed only with NMOS.

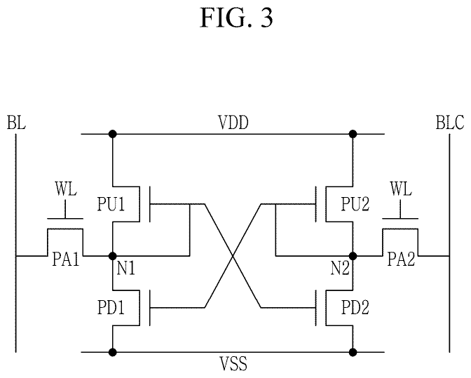

Hereinafter, a circuit diagram of a second layer 2000 of a semiconductor device according to an embodiment will be described. FIG. 3 illustrates a circuit diagram for explaining an SRAM cell of a semiconductor device according to an embodiment.

Referring to FIG. 3, the SRAM cell according to the present embodiment may include a first pull-up transistor PU1, a first pull-down transistor PD1, a second pull-up transistor PU2, a second pull-down transistor PD2, a first pass transistor PA1, and a second pass transistor PA2. The first pull-up transistor PU1, the second pull-up transistor PU2, the first pull-down transistor PD1, the second pull-down transistor PD2, the first pass transistor PA1, and the second pass transistor PA2 may be N-type transistors. In FIG. 3, a configuration in which all transistors in an SRAM cell are N-type transistors is described, but in an embodiment, all transistors in an SRAM cell may be P-type transistors.

Referring to FIG. 3, the source and drain of the first pass transistor PA1 may be connected to a first storage node N1 and a bit line BL, respectively. The first pass transistor PA1 may be gated by a gate signal line (e.g., the word line WL) to connect the first storage node N1 to the bit line BL. The source and drain of the second pass transistor PA2 may be connected to a second storage node N2 and a complementary bitline BLC, respectively. The second pass transistor PA2 may be gated by the gate signal line WL to connect the second storage node N2 to the complementary bitline BLC. In this case, the bit line BL may be complementary to the complementary bitline BLC. That is, a signal applied to the bit line BL may have a complementary relationship with a signal applied to the complementary bit line BLC. The gates of the first pass transistor PA1 and the second pass transistor PA2 may be electrically connected to the gate signal line WL.

Referring to FIG. 3, the gates of the first pull-up transistor PU1, the first pull-down transistor PD1, the second pull-up transistor PU2, and the second pull-down transistor PD2 can be connected. In addition, the drain of the first pass transistor PA1, the drain of the first pull-up transistor PU1, and the source of the second pull-down transistor PD2 may be connected to the first storage node N1, and the drain of the second pass transistor PA2, the drain of the second pull-up transistor PU2, and the source of the first pull-down transistor PD1 may be connected to the second storage node N2.

The first storage node N1 and the second storage node N2 may store SRAM data. Data stored in the first storage node N1 and data stored in the second storage node N2 may have a complementary relationship with each other. Specifically, when the voltage level of the first storage node N1 is a high level, the voltage level of the second storage node N2 may be a low level. Conversely, when the voltage level of the first storage node N1 is a low level, the voltage level of the second storage node N2 may be a high level.

In the SRAM, when the potential of the gate signal line WL becomes a first level (e.g., logic high), the first pass transistor PA1 and the second pass transistor PA2 may be turned on. Accordingly, a signal of the bit line BL may be applied to the first storage node N1, and a signal of the complementary bit line BLC may be applied to the second storage node N2. Data may be stored in the first storage node N1 and the second storage node N2 according to the signal of the bit line BL and the signal of the complementary bit line BLC. In addition, data stored in the first storage node N1 and the second storage node N2 may be read out according to the signal of the bit line BL and the signal of the complementary bit line BLC.

Hereinafter, a structure of a semiconductor device according to an embodiment will be described in detail with reference to the accompanying drawings.

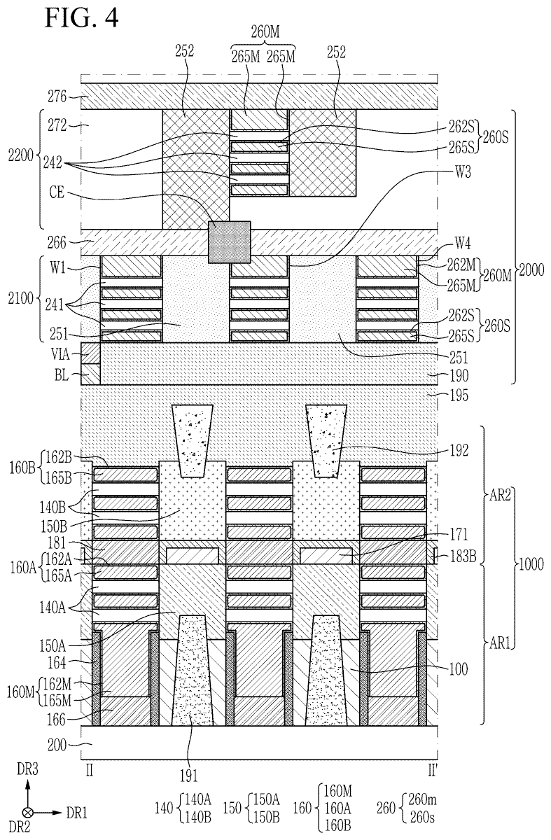

FIG. 4 illustrates a cross-sectional view of a semiconductor device according to an embodiment. FIG. 4 illustrates a cross-section of the laminate of FIG. 1 cut in a vertical direction. Referring to FIG. 4, the semiconductor device according to the present embodiment may include a first layer 1000 and a second layer 2000. As described in FIG. 1, the first layer 1000 may include PMOS and NMOS, and the second layer 2000 may include SRAM.

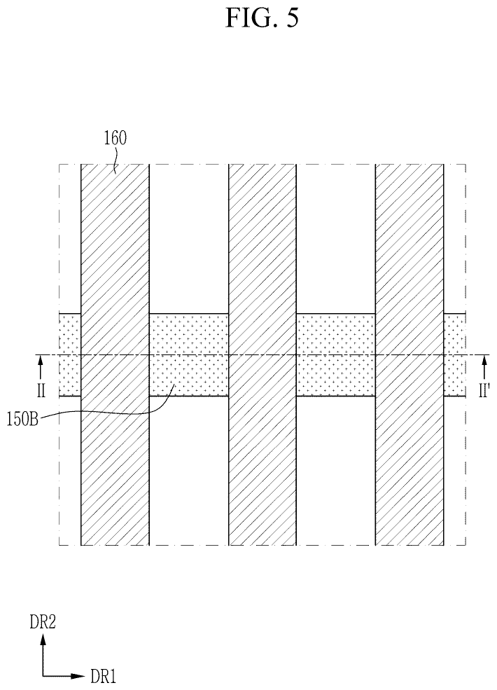

First, the first layer 1000 will be described. The first layer 1000 may include a first active region AR1 and a second active region AR2 stacked in a third direction DR3. The first layer 1000 of FIG. 4 may have a plan view as shown in FIG. 5, and FIG. 4 may correspond to a cross-section taken along a line II-II′ of the top plan view of FIG. 5. Hereinafter, embodiments of the present disclosure will be described with reference to FIG. 4 and FIG. 5 simultaneously.

Referring to FIG. 4 and FIG. 5, the first layer 1000 of the semiconductor device according to the embodiment may include a first channel pattern 140A, a second channel pattern 140B disposed on the first channel pattern 140A, a gate structure 160 surrounding the first channel pattern 140A and the second channel pattern 140B, first source/drain patterns 150A disposed on opposite sides of the first channel pattern 140A, and second source/drain patterns 150B disposed on opposite sides of the second channel pattern 140B.

The first channel pattern 140A may be disposed on a base insulating layer 200. The base insulating layer 200 may be an insulating substrate. The base insulating layer 200 may include an oxide, a nitride, an oxynitride, or a combination thereof. For example, the base insulating layer 200 may include a silicon oxide (SiO₂). Although the base insulating layer 200 is illustrated as being a single film, it is only for better understanding and ease of description, and is not limited thereto. For example, the base insulating layer 200 may include a plurality of layers (e.g., films).

The base insulating layer 200 may include an upper surface and a lower surface. The upper surface and the lower surface of the base insulating layer 200 may be formed as planes parallel to a first direction DR1 and a second direction DR2 intersecting the first direction DR1. The upper surface of the base insulating layer 200 may be a surface opposite to the lower surface of the base insulating layer 200 in the third direction DR3. The upper surface of the base insulating layer 200 may be referred to as a front side. The lower surface of the base insulating layer 200 may be referred to as a back side.

The first layer 1000 of the semiconductor device according to the embodiment may include at least one transistor structure. For example, the semiconductor device according to the embodiment may include a first transistor structure including a plurality of first channel patterns 140A and a second transistor structure including a plurality of second channel patterns 140B. The first and second transistor structures according to the embodiment may have a gate all around field effect transistor (GAAFET) structure such as an multi bridge channel field effect transistor (MBCFET™) in which the plurality of first channel patterns 140A and the plurality of second channel patterns (140B are surrounded by the gate structure 160.

The first and second transistor structures according to the embodiment may be formed to have a three dimensional-stacked FET (3DSFET) structure stacked in the third direction DR3. In this case, the first transistor structure may be one from among an N-type MOSFET and a P-type MOSFET, and the second transistor structure may be the other from among the P-type MOSFET and the N-type MOSFET. In the embodiment, each of the first and second transistor structures may be an N-type MOSFET and a P-type MOSFET, but is not limited thereto. Hereinafter, a case in which the plurality of first channel patterns 140A and the plurality of second channel patterns 140B are stacked in the third direction DR3 to form a 3DS FET structure will be described.

The plurality of channel patterns 140 may be disposed on the base insulating layer 200. In the embodiment, the plurality of channel patterns 140 may include the plurality of first channel patterns 140A disposed on the base insulating layer 200 and the plurality of second channel patterns 140B disposed on the plurality of first channel patterns 140A.

The plurality of first channel patterns 140A may be disposed on the upper surface of the base insulating layer 200. The plurality of first channel patterns 140A may be disposed spaced apart from each other in the third direction DR3. Here, the third direction DR3 may be a direction intersecting the first direction DR1 and the second direction DR2. For example, the third direction DR3 may be a thickness direction of the base insulating layer 200.

According to some embodiments, the widths of the plurality of first channel patterns 140A along the second direction DR2 may be substantially the same as each other. In contrast, the widths of the plurality of first channel patterns 140A along the second direction DR2 may decrease as they move away from the upper surface of the base insulating layer 200. As shown in FIG. 4, the widths of the plurality of first channel patterns 140A along the first direction DR1 may be substantially the same as each other. In contrast, the widths of the plurality of first channel patterns 140A along the first direction DR1 may decrease as they move away from the upper surface of the base insulating layer 200.

The plurality of second channel patterns 140B may be disposed on the plurality of first channel patterns 140A. Specifically, the plurality of second channel patterns 140B may be disposed spaced apart from the plurality of first channel patterns 140A in the third direction DR3. For example, as illustrated in FIG. 4, an intermediate insulating pattern 181 to be described later may be disposed on the plurality of first channel patterns 140A, and the plurality of second channel patterns 140B may be disposed on the intermediate insulating pattern 181. The second channel patterns 140B may be disposed spaced apart from the plurality of first channel patterns 140A in the third direction DR3 by the intermediate insulating pattern 181. The plurality of second channel patterns 140B may be disposed spaced apart from each other in the third direction DR3.

According to some embodiments, the widths of the plurality of second channel patterns 140B along the second direction DR2 may be substantially the same as each other. In contrast, the widths of the plurality of second channel patterns 140B along the second direction DR2 may decrease as they move away from the upper surface of the base insulating layer 200. As shown in FIG. 4, the widths of the plurality of second channel patterns 140B along the first direction DR1 may be substantially the same as each other. In contrast, the widths of the plurality of second channel patterns 140B along the first direction DR1 may decrease as they move away from the upper surface of the base insulating layer 200.

The plurality of first channel patterns 140A and the plurality of second channel patterns 140B may be multi-channel active patterns. As an example, the plurality of first channel patterns 140A and the plurality of second channel patterns 140B may have a nanosheet shape and may be semiconductor patterns including a semiconductor material.

The plurality of first channel patterns 140A and the plurality of second channel patterns 140B may be formed by etching a portion of a substrate, or may include an epitaxial layer grown from the substrate. The plurality of first channel patterns 140A and the plurality of second channel patterns 140B may include silicon (Si) or germanium (Ge), which is an elemental semiconductor material. In addition, the plurality of first channel patterns 140A and the plurality of second channel patterns 140B may include a compound semiconductor such as, for example, a group IV-IV compound semiconductor or a group III-V compound semiconductor.

The group IV-IV compound semiconductor may be, for example, a binary compound or a ternary compound including at least two or more from among carbon (C), silicon (Si), germanium (Ge), and tin (Sn).

The III-V group compound semiconductor may be, for example, a binary compound, a ternary compound, or a quaternary compound formed by combining at least one from among aluminum (Al), gallium (Ga), and indium (In) as group III elements with one of phosphorus (P), arsenic (As), and antimonium (Sb) as group V elements.

In the embodiment, the plurality of channel patterns 140 may include silicon (Si). As another example, the plurality of channel patterns 140 may include silicon germanium (SiGe).

In FIG. 4, two first channel patterns 140A and two second channel patterns 140B are illustrated as being stacked to be spaced apart from each other along the third direction DR3, but this is only for better understanding and ease of description and is not limited thereto. For example, three or more plurality of first channel patterns 140A and/or three or more plurality of second channel patterns 140B may be stacked to be spaced apart from each other along the third direction DR3. Alternatively, one first channel pattern 140A and/or one second channel pattern 140B may be stacked to be spaced apart from each other along the third direction DR3.

The semiconductor device according to the embodiment may further include the intermediate insulating pattern 181. The intermediate insulating pattern 181 may be disposed on the plurality of first channel patterns 140A.

The intermediate insulating pattern 181 may include various insulating materials. For example, the intermediate insulating pattern 181 may include a silicon oxide, a silicon nitride, a silicon oxynitride, or a combination thereof. The intermediate insulating pattern 181 may separate the plurality of first channel patterns 140A and the plurality of second channel patterns 140B from each other.

In FIG. 4, the intermediate insulating pattern 181 is illustrated as being formed of a single layer, but the intermediate insulating pattern 181 may be formed of two or more layers. For example, the intermediate insulating pattern 181 may include a plurality of insulating layers. Even in this case, the plurality of second channel patterns 140B and the plurality of first channel patterns 140A may be separated by the intermediate insulating pattern 181.

Portions of the gate structure 160 may be disposed to be spaced apart from each in the first direction DR1 and may extend in the second direction DR2. The gate structure 160 may surround each of the plurality of channel patterns 140.

The first transistor structure may include a plurality of first channel patterns 140A, a gate structure 160 surrounding the plurality of first channel patterns 140A, and a first source/drain pattern 150A connected to the plurality of first channel patterns 140A on one side of the gate structure 160. In addition, the second transistor structure may include a plurality of second channel patterns 140B, a gate structure 160 surrounding the plurality of second channel patterns 140B, and a second source/drain pattern 150B connected to the plurality of second channel patterns 140B on one side of the gate structure 160.

In the embodiment, a single gate structure 160 may be configured to surround the plurality of first channel patterns 140A and the plurality of second channel patterns 140B, such that the first and second transistor structures share a single gate structure 160. Alternatively, the first gate structure 160A surrounding the first channel patterns 140A and the second gate structure 160B surrounding the second channel patterns 140B may include different materials from each other. Although a configuration in which the first and second transistor structures share one gate structure 160 is described for the present embodiment, this is only an example and the present disclosure is not limited thereto.

The gate structure 160 may include a first gate structure 160A, a second gate structure 160B, and a main gate structure 160M. The first gate structure 160A may be disposed between the plurality of first channel patterns 140A adjacent to each other in the third direction DR3, and between an uppermost one of the first channel patterns 140A and the intermediate insulating pattern 181. The second gate structure 160B may be disposed between the plurality of second channel patterns 140B adjacent to each other in the third direction DR3, and between a lowermost one of the second channel patterns 140B and the intermediate insulating pattern 181. The main gate structure 160M may be disposed on (e.g., below) a lowermost one of the first channel patterns 140A. That is, in the present embodiment, the main gate structure 160M may be disposed at a lowermost side.

The first gate structure 160A may be adjacent to the first source/drain pattern 150A, which will be described later. The second gate structure 160B may be adjacent to the second source/drain pattern 150B, which will be described later. The main gate structure 160M may be disposed between the base insulating layer 200 and the lowermost one of the first channel patterns 140A.

According to the embodiment, the first gate structures 160A and the second gate structures 160B may be alternately stacked with the plurality of channel patterns 140. Referring to FIG. 4, the first gate structures 160A may be alternately stacked with the plurality of first channel patterns 140A. In FIG. 4, two first gate structures 160A and two first channel patterns 140A are alternately stacked, but the number of first gate structures 160A and first channel patterns 140A that are alternately stacked is not limited. Referring to FIG. 4, the second gate structures 160B may be alternately stacked with the plurality of second channel patterns 140B. In FIG. 4, three second gate structures 160B and two second channel patterns 140B are alternately stacked, but the number of second gate structures 160B and second channel patterns 140B that are alternately stacked is not limited.

The first gate structure 160A and the second gate structure 160B may include gate electrodes (e.g., a first gate electrode 165A and a second gate electrode 165B), and gate insulating films (e.g., a first gate insulating film 162A and a second gate insulating film 162B), respectively.

The gate electrodes (e.g., the first gate electrode 165A and the second gate electrode 165B) may surround the plurality of channel patterns 140. For example, the first gate electrode 165A may surround the plurality of first channel patterns 140A, and the second gate electrode 165B may surround the plurality of second channel patterns 140B.

In addition, at least some of the gate electrodes (e.g., the first gate electrode 165A and the second gate electrode 165B) may be disposed between the plurality of channel patterns 140. For example, at least one first gate electrode 165A may be disposed between the plurality of first channel patterns 140A, and at least one second gate electrode 165B may be disposed between the plurality of second channel patterns 140B.

The gate electrodes (e.g., the first gate electrode 165A and the second gate electrode 165B) may include a conductive material. The gate electrodes (e.g., the first gate electrode 165A and the second gate electrode 165B) may include at least one from among a metal, a metal alloy, a conductive metal nitride, a metal silicide, a doped semiconductor material, a conductive metal oxide, and a conductive metal nitride. The gate electrodes (e.g., the first gate electrode 165A and the second gate electrode 165B) may include, for example, at least one from among a titanium nitride (TiN), a tantalum carbide (TaC), a tantalum nitride (TaN), a titanium silicon nitride (TiSiN), a tantalum silicon nitride (TaSiN), a tantalum titanium nitride (TaTiN), a titanium aluminum nitride (TiAlN), a tantalum aluminum nitride (TaAlN), a tungsten nitride (WN), ruthenium (Ru), a titanium aluminum (TiAl), a titanium aluminum carbonitride (TiAlC-N), a titanium aluminum carbide (TiAlC), a titanium carbide (TiC), a tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), a niobium nitride (NbN), a niobium carbide (NbC), molybdenum (Mo), a molybdenum nitride (MoN), a molybdenum carbide (MoC), a tungsten carbide (WC), rhodium (Rh), palladium (Pd), iridium (Ir), osmium (Os), silver (Ag), gold (Au), zinc (Zn), vanadium (V), and a combination thereof, but is not limited thereto. The conductive metal oxide and the conductive metal oxynitride may include oxidized forms of the above-mentioned materials, but are not limited thereto. The gate electrodes (e.g., the first gate electrode 165A and the second gate electrode 165B) may include the same material as each other, but are not limited thereto, and the gate electrodes (e.g., the first gate electrode 165A and the second gate electrode 165B) may include different materials from each other.

The gate insulating films (e.g., the first gate insulating film 162A and the second gate insulating film 162B) may be disposed along the circumference of the plurality of channel patterns 140. For example, the first gate insulating film 162A may be disposed along the circumference of each of the plurality of first channel patterns 140A, and the second gate insulating film 162B may be disposed along the circumference of each of the plurality of second channel patterns 140B.

The first gate insulating films 162A may be in direct contact with the plurality of first channel patterns 140A and the intermediate insulating pattern 181. The second gate insulating films 162B may be in direct contact with the plurality of second channel patterns 140B and the intermediate insulating pattern 181. The gate insulating films (e.g., the first gate insulating film 162A and the second gate insulating film 162B) may be interposed between the plurality of channel patterns 140 and the gate electrodes (e.g., the first gate electrode 165A and the second gate electrode 165B). The gate insulating films (e.g., the first gate insulating film 162A and the second gate insulating film 162B) may include various insulating materials.

In the embodiment, the gate insulating films (e.g., the first gate insulating film 162A and the second gate insulating film 162B) are illustrated as a single film, but the present disclosure is not limited thereto. For example, the gate insulating films (e.g., the first gate insulating film 162A and the second gate insulating film 162B) may be formed of multiple films including a silicon oxide (SiO₂) and a high dielectric constant material. In this case, the high dielectric constant material may include a material having a higher dielectric constant than a dielectric constant of a silicon oxide (SiO₂) such as a hafnium oxide (HfO), an aluminum oxide (AlO), or a tantalum oxide (TaO).

The main gate structure 160M may be disposed under the first gate structure 160A and the plurality of first channel patterns 140A. The main gate structure 160M may be disposed on a lower surface of a lowermost one of the first channel patterns 140A.

The main gate structure 160M may include a main gate electrode 165M and a main gate insulating film 162M.

The main gate electrode 165M may be disposed under the first gate structures 160A and the plurality of first channel patterns 140A. The main gate electrode 165M may be disposed on a lower surface of the lowermost one of the first channel patterns 140A. Accordingly, four surfaces of the plurality of channel patterns 140 may be surrounded by the gate electrodes (e.g., the first gate electrode 165A and the second gate electrode 165B) and the main gate electrode 165M. The main gate electrode 165M may include the same conductive material as a conductive material of the gate electrodes (e.g., the first gate electrode 165A and the second gate electrode 165B). For example, the main gate electrode 165M may include at least one from among a metal, a metal alloy, a conductive metal nitride, a metal silicide, a doped semiconductor material, a conductive metal oxide, and a conductive metal nitride.

The main gate insulating film 162M may extend along the side surface of the main gate electrode 165M. The main gate insulating film 162M may extend along the side surface of a gate spacer 164. The main gate insulating film 162M may include various insulating materials.

In the embodiment, the main gate insulating film 162M is shown as a single film, but is not limited thereto. For example, the main gate insulating layer 162M may be formed as a multi-film including a silicon oxide (SiO₂) and a high dielectric constant material. In this case, the high dielectric constant material may include a material having a higher dielectric constant than a dielectric constant of a silicon oxide (SiO₂) such as a hafnium oxide (HfO), an aluminum oxide (AlO), or a tantalum oxide (TaO).

The semiconductor device according to the embodiment may further include the gate spacer 164 and a capping layer 166.

The capping layer 166 may be disposed under the main gate structure 160M. Both side surfaces of the capping layer 166 may be in contact with the gate spacer 164. According to some embodiments, the capping layer 166 may cover the upper surface of the gate spacer 164.

The capping layer 166 may include at least one from among, for example, a silicon nitride (SiN), a silicon oxynitride (SiON), a silicon carbonitride (SiCN), a silicon carbonitride (SiOCN), and a combination thereof. The capping layer 166 may include a material having etch selectivity with respect to a second interlayer insulating layer 171 to be described later.

The gate spacer 164 may be disposed on the side surface of the main gate electrode 165M. In the embodiment, the gate spacer 164 may also be disposed on the side surface of the capping layer 166. The gate spacer 164 may not be disposed on the side surfaces of first gate electrode 165A and the second gate electrode 165B. The gate spacer 164 may not be disposed on the side surface of each of the first channel patterns 140A and the second channel patterns 140B. The gate spacer 164 may not be disposed between the plurality of channel patterns (e.g., the first channel patterns 140A and the second channel patterns 140B) adjacent to each other in the third direction DR3. Although the gate spacer 164 is illustrated as being a single film, it is only for better understanding and ease of description, and is not limited thereto. For example, the gate spacer 164 may include a plurality of layers (e.g., films).

The gate spacer 164 may include at least one from among, for example, a silicon nitride (SiN), a silicon oxynitride (SiON), a silicon oxide (SiO₂), a silicon carbonate nitride (SiOCN), a silicon boron nitride (SiBN), a silicon oxyboron nitride (SiOBN), a silicon oxycarbide (SiOC), and a combination thereof.

The source/drain patterns 150 may be disposed on at least one side of the gate structure 160. For example, the source/drain patterns 150 may be disposed on opposite sides of the gate structure 160. For example, each of the source/drain patterns 150 may be disposed between two gate structures 160 arranged to be spaced apart from each other in the first direction DR1. The source/drain patterns 150 may be in contact with the side surfaces of a plurality of channel patterns 140. The source/drain patterns 150 may be connected to the plurality of channel patterns 140. The source/drain patterns 150 according to the embodiment may include a first source/drain pattern 150A and a second source/drain pattern 150B.

The first source/drain pattern 150A may be disposed on at least one side of the first gate structure 160A. For example, a plurality of first source/drain patterns 150A may be disposed on opposite sides of the first gate structure 160A. For example, each of the first source/drain patterns 150A may be disposed between two first gate structures 160A arranged to be spaced apart from each other in the first direction DR1. The first source/drain pattern 150A may be connected to the plurality of first channel patterns 140A.

The first source/drain pattern 150A may be epitaxial patterns formed by a selective epitaxial growth process using the plurality of first channel patterns 140A as seeds. The first source/drain patterns 150A may serve as a source/drain of a first transistor structure that uses the plurality of first channel patterns 140A as channel regions.

The first source/drain pattern 150A may include a semiconductor material. The first source/drain pattern 150A may include, for example, silicon (Si) or germanium (Ge). In addition, the first source/drain pattern 150A may include, for example, a binary compound or a ternary compound containing two or more of carbon (C), silicon (Si), germanium (Ge), and tin (Sn). For example, the first source/drain pattern 150A may include silicon (Si), silicon-germanium (SiGe), germanium (Ge), silicon carbide (SiC), and the like, but is not limited thereto. In the embodiment, the first source/drain pattern 150A is illustrated as being formed of a single layer, but the present disclosure is not limited thereto, and the first source/drain pattern 150A may be formed of two or more layers. For example, the first source/drain pattern 150A may be formed of a first layer conformally disposed in a recess region defined by the side surfaces of the first channel patterns 140A and the first gate structures 160A, and a second layer filling the recess region above the first layer. In this case, the concentrations of silicon (Si) or germanium (Ge) included in the first layer and second layer may be different from each other. For example, the concentration of germanium (Ge) included in the first layer may be greater than the concentration of germanium (Ge) included in the second layer.

In the embodiment, the first source/drain pattern 150A may be doped with impurities. For example, when the first transistor structure is a P-type MOSFET, the first source/drain pattern 150A may include a P-type impurity. For example, the first source/drain pattern 150A may include boron (B), aluminum (Al), gallium (Ga), or a combination thereof.

The semiconductor device according to the embodiment may further include a first interlayer insulating layer 100 disposed below the first source/drain pattern 150A. The first interlayer insulating layer 100 may be disposed between the first source/drain pattern 150A and the base insulating layer 200.

The first interlayer insulating layer 100 may cover the first source/drain pattern 150A.

The first interlayer insulating layer 100 may be disposed between two adjacent main gate structures 160M along the first direction DR1. At least some region of the first interlayer insulating layer 100 may overlap with the main gate structure 160M in the first direction DR1. An upper surface of the first interlayer insulating layer 100 may have a flat shape. The upper surface of the first interlayer insulating layer 100 may be disposed on the same plane as the upper surfaces of the gate spacer 164 and the capping layer 166. The first interlayer insulating layer 100 may not be disposed on the upper surfaces of the gate spacer 164 and the capping layer 166.

The first interlayer insulating layer 100 may include an insulating material. The first interlayer insulating layer 100 may include at least one from among, for example, a silicon nitride (SiN), a silicon oxynitride (SiON), a silicon oxide (SiO₂), a silicon carbonate nitride (SiOCN), a silicon boron nitride (SiBN), a silicon oxyboron nitride (SiOBN), a silicon oxycarbide (SiOC), and a combination thereof. Although the first interlayer insulating layer 100 is illustrated as being a single film, it is only for better understanding and ease of description, and is not limited thereto. For example, the first interlayer insulating layer 100 may include a plurality of layers (e.g., films).

The second source/drain pattern 150B of the semiconductor device according to the embodiment may be disposed on the first source/drain pattern 150A. The second source/drain pattern 150B may be disposed to be spaced apart from the first source/drain pattern 150A in the third direction DR3. Referring to FIG. 4, the second source/drain pattern 150B and the first source/drain pattern 150A may be spaced apart from each other in the third direction DR3 by the second interlayer insulating layer 171 and a second barrier pattern 183B.

The second source/drain patterns 150B may be disposed on the second barrier pattern 183B. The lower surface of each of the second source/drain patterns 150B may be in contact with the upper surface of the second barrier pattern 183B. The second source/drain pattern 150B may be disposed on at least one side of the second gate structure 160B. For example, a plurality of the second source/drain pattern 150B may be disposed on opposite sides of the second gate structure 160B. For example, each of the second source/drain patterns 150B may be disposed between two second gate structures 160B arranged to be spaced apart from each other in the first direction DR1. The second source/drain pattern 150B may be connected to the plurality of second channel patterns 140B. The second source/drain pattern 150B may be in contact with the side surfaces of the plurality of second channel patterns 140B.

The second source/drain pattern 150B may be an epitaxial pattern formed by a selective epitaxial growth process using the plurality of second channel patterns 140B as seeds. In this case, the second source/drain pattern 150B may be a pattern formed by using opposite side surfaces of the plurality of second channel patterns 140B as seeds.

The second source/drain pattern 150B may serve as a source/drain of a second transistor structure that uses the plurality of second channel patterns 140B as channel regions.

In the embodiment, the lower surface of the second source/drain pattern 150B may be disposed at substantially the same level as the lower surface of the lowermost one of the second channel patterns 140B. In the embodiment, the upper surface of the second source/drain pattern 150B may be disposed at a level higher or lower than the upper surface of the uppermost one of the second gate structures 160B. The lower surface of the second source/drain pattern 150B may be disposed at substantially the same level as the lower surface of the second gate structure 160B disposed at the lowermost side. However, it is not limited thereto, and the lower surface of the second source/drain pattern 150B may be disposed at a level higher or lower than the lower surface of the lowermost one of the second channel patterns 140B.

The second source/drain pattern 150B may include a semiconductor material. The second source/drain pattern 150B may include the same material as a material of the first source/drain pattern 150A. The second source/drain pattern 150B may include, for example, silicon (Si) or germanium (Ge). In addition, the second source/drain pattern 150B may include, for example, a binary compound or a ternary compound containing two or more from among carbon (C), silicon (Si), germanium (Ge), and tin (Sn). For example, the second source/drain pattern 150B may include silicon (Si), silicon-germanium (SiGe), germanium (Ge), silicon carbide (SiC), and the like, but is not limited thereto. In the embodiment, the second source/drain pattern 150B is illustrated as being formed of a single layer, but the present disclosure is not limited thereto, and the second source/drain pattern 150B may be formed of two or more layers. When the second source/drain pattern 150B includes two or more layers, the concentrations of silicon (Si) or germanium (Ge) included in respective layers may be different from each other.

In the embodiment, the second source/drain pattern 150B may be doped with impurities. For example, when the second transistor structure is an N-type MOSFET, the second source/drain pattern 150B may include an N-type impurity. For example, the second source/drain pattern 150B may include phosphorus (P), antimony (Sb), arsenic (As), or a combination thereof.

The semiconductor device according to the embodiment may further include the second barrier pattern 183B and the second interlayer insulating layer 171 disposed between the second source/drain pattern 150B and the first source/drain pattern 150A.

The second barrier pattern 183B may cover the second source/drain pattern 150B. According to some embodiments, the second barrier pattern 183B may be omitted. In this case, the upper surface and side surface of the second source/drain pattern 150B may be in contact with the second interlayer insulating layer 171.

The second barrier pattern 183B may include an insulating material. The second barrier pattern 183B may include at least one from among, for example, a silicon nitride (SiN), a silicon oxynitride (SiON), a silicon oxide (SiO₂), a silicon carbonate nitride (SiOCN), a silicon boron nitride (SiBN), a silicon oxyboron nitride (SiOBN), a silicon oxycarbide (SiOC), and a combination thereof. Although the second barrier pattern 183B is illustrated as being a single film, it is only for better understanding and ease of description, and is not limited thereto. For example, the second barrier pattern 183B may include a plurality of layers (e.g., films).

The second interlayer insulating layer 171 may cover the second source/drain pattern 150B together with the second barrier pattern 183B. The second interlayer insulating layer 171 may be disposed below the second barrier pattern 183B. The second interlayer insulating layer 171 may include an insulating material. The second interlayer insulating layer 171 may include the same insulating material as an insulating material of the first interlayer insulating layer 100. However, it is not limited thereto, and the second interlayer insulating layer 171 may include an insulating material different from the insulating material of the first interlayer insulating layer 100. The second interlayer insulating layer 171 may include at least one from among, for example, a silicon nitride (SiN), a silicon oxynitride (SiON), a silicon oxide (SiO₂), a silicon carbonate nitride (SiOCN), a silicon boron nitride (SiBN), a silicon oxyboron nitride (SiOBN), a silicon oxycarbide (SiOC), and a combination thereof. Although the second interlayer insulating layer 171 is illustrated as being a single film, it is only for better understanding and ease of description, and is not limited thereto. For example, the second interlayer insulating layer 171 may include a plurality of layers (e.g., films).

Referring to FIG. 4, a first contact electrode 191 penetrating the first interlayer insulating layer 100 and contacting the first source/drain pattern 150A may be provided. The first contact electrode 191 may be electrically connected to the first source/drain pattern 150A. The first contact electrode 191 may include at least one from among a metal, a metal alloy, a conductive metal nitride, a conductive metal carbide, a conductive metal oxide, a conductive metal carbonitride, and a two-dimensional (2D) material. The metal may include at least one from among titanium (Ti), tantalum (Ta), tungsten (W), nickel (Ni), cobalt (Co), and platinum (Pt). The conductive metal nitride may include at least one from among a titanium nitride (TiN), a tantalum nitride (TaN), a tungsten nitride (WN), a nickel nitride (NiN), a cobalt nitride (CoN), and a platinum nitride (PtN).

According to some embodiments in the cross-sectional view of FIG. 4, the first contact electrode 191 may be connected to a wire that transmits an electrical signal or power voltage supplied from the outside, and may provide the electrical signal or power voltage to the first source/drain pattern 150A.

According to some embodiments, a plurality of the first contact electrodes 191 may be provided and electrically connected to the plurality of first source/drain patterns 150A, respectively.

In addition, an upper insulating layer 195 may be disposed on the second active region AR2. The upper insulating layer 195 may include an insulating material. A second contact electrode 192 may be disposed on the upper insulating layer 195. The second contact electrode 192 may be electrically connected to the second source/drain pattern 150B. The second contact electrode 192 may include at least one from among a metal, a metal alloy, a conductive metal nitride, a conductive metal carbide, a conductive metal oxide, a conductive metal carbonitride, and a two-dimensional (2D) material. The metal may include at least one from among titanium (Ti), tantalum (Ta), tungsten (W), nickel (Ni), cobalt (Co), and platinum (Pt). The conductive metal nitride may include at least one from among a titanium nitride (TiN), a tantalum nitride (TaN), a tungsten nitride (WN), a nickel nitride (NiN), a cobalt nitride (CoN), and a platinum nitride (PtN).

According to some embodiments in the cross-sectional view of FIG. 4, the second contact electrode 192 may be connected to a wire that transmits an electrical signal or power voltage supplied from the outside, and may provide the electrical signal or power voltage to the second source/drain pattern 150B.

According to some embodiments, a plurality of the second contact electrodes 192 may be provided and electrically connected to the plurality of second source/drain patterns 150B, respectively.

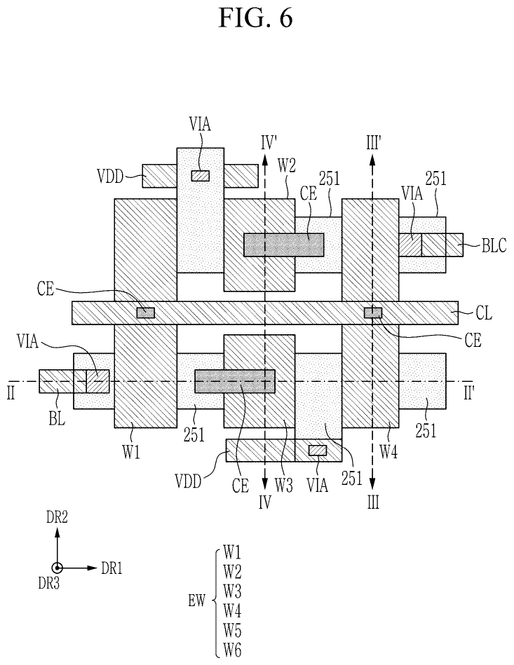

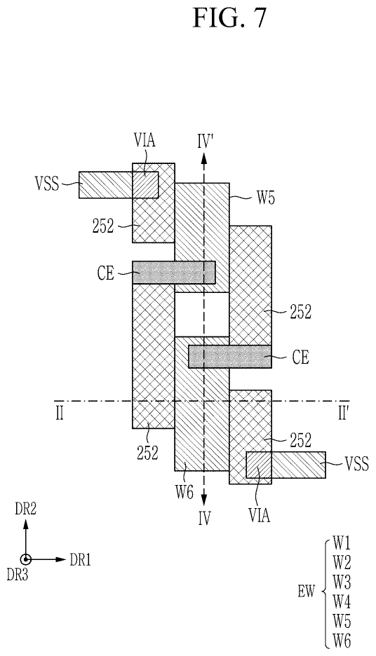

Hereinafter, the stacked structure of the second layer 2000 will be described. Referring to FIG. 4, an interlayer insulating layer 190 (e.g., an interlayer insulating film) may be disposed on the first layer 1000. The interlayer insulating layer 190 may include an insulating material. The cross-section of the second layer 2000 in FIG. 4 may be a cross-section taken along a line II-II′ of the top plan views shown in FIG. 6 and FIG. 7. Accordingly, the structure of the second layer 2000 will be described with reference to FIG. 4, FIG. 6, and FIG. 7 simultaneously. The second layer 2000 of FIG. 4 may include a first portion 2100 and a second portion 2200. FIG. 6 illustrates a top plan view of the first portion 2100, and FIG. 7 illustrates a top plan view of the second portion 2200.

That is, for better understanding and ease of description, the top plan view of the second layer 2000 is divided into FIG. 6 and FIG. 7. As shown in FIG. 4, the second layer 2000 may have a structure in which the first portion 2100 and the second portion 2200 are stacked. First, the structure of the first portion 2100 will be described.

Referring to FIG. 4 and FIG. 6, a plurality of third channel patterns 241 may be disposed. As shown in FIG. 4, the plurality of third channel patterns 241 may be disposed to be spaced apart from each other in the third direction DR3. The third channel pattern 241 may include IGZO or a two-dimensional material. The two-dimensional material may include, for example, at least one from among molybdenum disulfide (MoS₂), molybdenum diselenide (MoSe₂), tungsten disulfide (WS₂), tungsten diselenide (WSe₂), and black phosphorus (BP), but is not limited thereto.

A third source/drain pattern 251 may be disposed between the third channel patterns 241. Referring to FIG. 4, a plurality of the third channel pattern 241 may be spaced apart in the first direction DR1, and the third source/drain pattern 251 may be disposed in a space where the third channel patterns 241 are not formed. The third source/drain pattern 251 may function as the source/drain of each transistor. In the embodiment, the third source/drain pattern 251 may include a metal.

In addition, at least one wire EW may be disposed along the second direction DR2. The at least one wire EW may include a first wire W1, a second wire W2, a third wire W3, a fourth wire W4, a fifth wire W5, and a sixth wire W6. The first wire W1, the second wire W2, the third wire W3, and the fourth wire W4 may function as a gate structure 260 of each transistor. As will be described separately later, the first wire W1 and the fourth wire W4 may be word lines WL. That is, the first wire W1 and the fourth wire W4 may correspond to the word lines WL of the circuit diagram illustrated in FIG. 3.

As shown in FIG. 4, at least a portion of each gate structure 260 may be disposed between the plurality of third channel patterns 241.

The gate structure 260 may include a main gate structure 260M and a sub-gate structure 260S. The main gate structure 260M may include a main gate electrode 265M and a main gate insulating film 262M surrounding the main gate electrode 265M. The upper surface of the main gate electrode 265M may be capped with an intermediate capping layer 266. That is, the main gate insulating film 262M may not be disposed on the upper surface of the main gate electrode 265M, but rather the intermediate capping layer 266 may be disposed thereon. As will be described separately later, the third source/drain pattern 251 and a fourth source/drain pattern 252 may be electrically connected through a connection electrode CE penetrating the intermediate capping layer 266.

The sub-gate structure 260S may include a sub-gate electrode 265S and a sub-gate insulating film 262S surrounding the sub-gate electrode 265S.

Referring to FIG. 6, a bit line BL, a driving voltage line VDD, a complementary bit line BLC, and a connection line CL may be disposed to extend along the first direction DR1. These wires and the third source/drain pattern 251 may be connected through a connection electrode CE and a via. As illustrated in FIG. 4, one or more from among the bit line BL, the driving voltage line VDD, the complementary bit line BLC, and the via VIA illustrated in FIG. 6 may be disposed in the interlayer insulating layer 190. That is, one or more from among the bit line BL, the driving voltage line VDD, the complementary bit line BLC, and the via VIA may be disposed below the plurality of third channel patterns 241 and the at least one wire EW.

The second layer 2000 may have a structure in which the first portion 2100 and the second portion 2200 are stacked. A planar shape of the second portion 2200 will be described with reference to FIG. 7. Referring to FIG. 4 and FIG. 7, a plurality of fourth channel patterns 242 may be disposed to be spaced apart from each other in the third direction DR3. The fourth channel pattern 242 may include IGZO or a two-dimensional material. The two-dimensional material may include, for example, at least one from among molybdenum disulfide (MoS₂), molybdenum diselenide (MoSe₂), tungsten disulfide (WS₂), tungsten diselenide (WSe₂), and black phosphorus (BP), but is not limited thereto.

At least one fourth source/drain pattern 252 be disposed between the fourth channel patterns 242. Referring to FIG. 4, the fourth source/drain patterns 252 may be disposed on respective sides of the fourth channel patterns 242. The fourth source/drain pattern 252 may function as the source/drain of each transistor. In the embodiment, the fourth source/drain pattern 252 may include a metal.

Referring to FIG. 7, the fifth wire W5 and the sixth wire W6 may be disposed along the second direction DR2. The fifth wire W5 may be disposed to overlap with the second wire W2 in the third direction DR3, and the sixth wire W6 may be disposed to overlap with the third wire W3 in the third direction DR3. The fifth wire W5 and the sixth wire W6 may function as the gate structure 260 of each transistor. The connection electrode CE may be disposed to extend along the first direction DR1, and the connection electrode CE may electrically connect the fifth wire W5 and the sixth wire W6 to the fourth source/drain pattern 252, respectively.

Referring to FIG. 7, a ground voltage line VSS may be disposed to extend along the first direction DR1. The ground voltage line VSS may be connected to the fourth source/drain pattern 252 through the via VIA.

The ground voltage line VSS and the connection electrode CE shown in FIG. 7 may be disposed above the fourth channel pattern 242, the fifth wire W5, and the sixth wire W6. That is, the connection between the third source/drain pattern 251 and the wires in the first portion 2100 of the second layer 2000 may be made under the third source/drain pattern 251, and the connection between the fourth source/drain pattern 252 and the wires in the second portion 2200 thereof may be made on the fourth source/drain pattern 252.

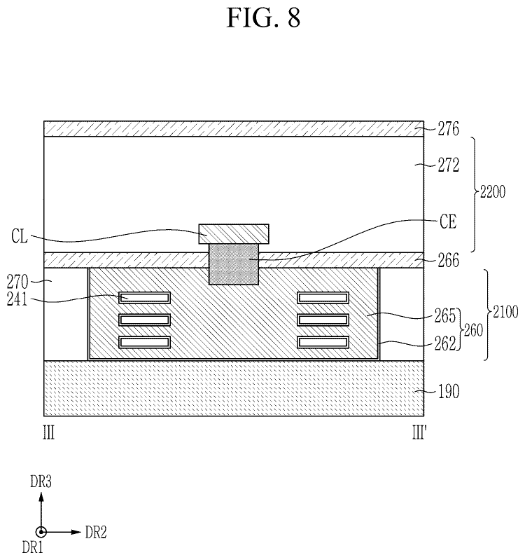

FIG. 8 illustrates a cross-sectional view taken along a line III-III′ of FIG. 6. Referring to FIG. 8, a plurality of third channel patterns 241, a gate insulating film 262 surrounding the same, and a gate electrode 265 may disposed on the interlayer insulating layer 190. The gate electrode 265 and the gate insulating film 262 may form the gate structure 260. As shown in FIG. 8, the gate electrode 265 may be integrally formed along the second direction DR2. The intermediate capping layer 266 may be disposed on the gate electrode 265. The connection electrode CE may be disposed through the intermediate capping layer 266, and the connection electrode CE may be connected to the connection line CL. The connection electrode CE may penetrate the intermediate capping layer 266 to be in direct contact with the gate electrode 265, and thus a voltage may be applied to the gate electrode 265. As shown in FIG. 8, a first insulating film 270 may be disposed in a portion of the first portion 2100 where the gate electrode 265 is not disposed, and a second insulating film 272 may be disposed in the second portion 2200. As shown in FIG. 8, an upper capping layer 276 may be disposed on the upper surface of the second portion 2200.

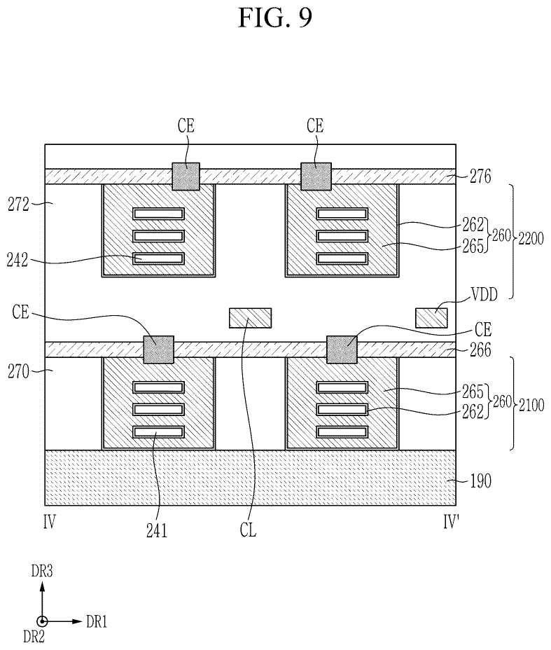

FIG. 9 illustrates a cross-sectional view taken along a line IV-IV′ of FIG. 6 and FIG. 7. Referring to FIG. 9, in the first portion 2100, a plurality of third channel patterns 241, a gate insulating film 262 surrounding the same, and a gate electrode 265 may be disposed on the interlayer insulating layer 190. The gate electrode 265 and the gate insulating film 262 may form the gate structure 260. The intermediate capping layer 266 may be disposed on the gate electrode 265. The connection electrode CE may be disposed through the intermediate capping layer 266. In addition, a plurality of fourth channel patterns 242, a gate insulating film 262 surrounding the same, and a gate electrode 265 may be disposed in the second portion 2200. The gate electrode 265 and the gate insulating film 262 may form the gate structure 260. An upper capping layer 276 may be disposed on the upper surface of the second portion 2200, and a connection electrode CE may be disposed through the upper capping layer 276. Referring to FIG. 9, FIG. 6, and FIG. 7 simultaneously, each connection electrode CE may connect the third source/drain pattern 251 to the gate electrode 265, or the fourth source/drain pattern 252 to the gate electrode 265. In the first portion 2100, a first insulating film 270 may be disposed in a region where the gate structure 260 is not disposed, and in the second portion 2200, a second insulating film 272 may be disposed in a region where the gate structure 260 is not disposed. As shown in FIG. 9, the connection line CL may be disposed between the first portion 2100 and the second portion 2200.

Referring to FIG. 4 and FIG. 6, the first wire W1 overlapping with the third channel pattern 241 and the third source/drain patterns 251 disposed on opposite sides of the first wire W1 may configure the first pass transistor PA1 of FIG. 2. The first wire W1 may be a gate, the third channel pattern 241 may be a channel, and the third source/drain patterns 251 disposed on opposite sides may be a source and a drain.

In addition, the third wire W3 overlapping with the third channel pattern 241 and the third source/drain patterns 251 disposed on opposite sides of the third wire W3 may configure the first pull-up transistor PU1 of FIG. 2. Similarly, the second wire W2 overlapping with the third channel pattern 241 and the third source/drain patterns 251 disposed on opposite sides of the second wire W2 may configure the second pull-up transistor PU2 of FIG. 2. The fourth wire W4 overlapping with the third channel pattern 241 and the third source/drain patterns 251 disposed on opposite sides of the fourth wire W4 may configure the second pass transistor PA2 of FIG. 2.

Referring to FIG. 4 and FIG. 7, the fifth wire W5 overlapping with the fourth channel pattern 242 and the fourth source/drain patterns 252 disposed on opposite sides of the fifth wire W5 may configure the first pull-down transistor PD1 of FIG. 2. In addition, the sixth wire W6 overlapping with the fourth channel pattern 242 and the fourth source/drain patterns 252 disposed on opposite sides of the sixth wire W6 may configure the second pull-down transistor PD2 of FIG. 2.

Referring to FIG. 4, the third source/drain pattern 251 and the fourth source/drain pattern 252 may be connected to the connection electrode CE. That is, as shown in FIG. 2, the drain of the first pull-up transistor PU1 and the source of the second pull-down transistor PD2 of FIG. 2 may be connected.

However, the planar arrangement and cross-sectional arrangement of the second layer 2000 described above are examples, and the present disclosure is not limited thereto.

In FIG. 4 and FIG. 6 to FIG. 9, a configuration in which the second layer 2000 includes a stacked structure of the first portion 2100 and the second portion 2200 is illustrated, but in an embodiment, the second layer 2000 may be disposed as a single layer. That is, as shown in FIG. 4 and FIG. 6 to FIG. 9, rather than having a structure in which a plurality of transistors are stacked, all transistors may be disposed in the same layer.

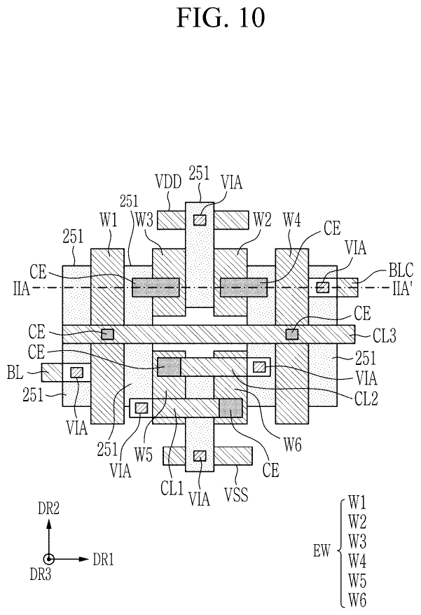

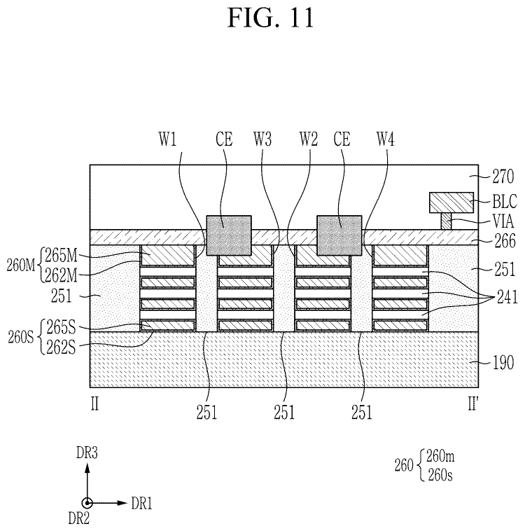

FIG. 10 illustrates a planar layout of a second layer 2000 according to an embodiment, and FIG. 11 illustrates a cross-sectional view taken along a line IIA-IIA′ of FIG. 10.

Referring to FIG. 10 and FIG. 11, in the semiconductor device according to the present embodiment, the first wire W1, the second wire W2, the third wire W3, the fourth wire W4, the fifth wire W5, and the sixth wire W6 may be disposed in the same layer. The first wire W1, the second wire W2, the third wire W3, the fourth wire W4, the fifth wire W5, and the sixth wire W6 may be disposed to extend along the second direction DR2, and the third channel pattern 241 may be disposed by overlapping respective wires. The description of the third channel pattern 241 is omitted as it is the same as described above. A third source/drain pattern 251 may be disposed between the third channel patterns 241. The description of the third source/drain pattern 251 may be the same as the description of the third source/drain pattern 251 provided above, and repeated description thereof may be omitted.

The bit line BL, the driving voltage line VDD, the complementary bit line BLC, the ground voltage line VSS, and connection lines CL1, CL2, and CL3 may be disposed to extend along the first direction DR1.

The bit line BL, the driving voltage line VDD, the complementary bit line BLC, the ground voltage line VSS, and the third source/drain pattern 251 may be connected through the via VIA or the connection electrode CE. In addition, the connection lines CL1, CL2, and CL3 and the at least one wire EW may be connected through the connection electrode CE or the via VIA. Even in the embodiments of FIG. 10 and FIG. 11, the first wire W1 overlapping with the third channel pattern 241 and the third source/drain patterns 251 disposed on opposite sides of the first wire W1 may configure the first pass transistor PA1 of FIG. 2. The first wire W1 may be a gate, the third channel pattern 241 may be a channel, and the third source/drain patterns 251 disposed on opposite sides may be a source and a drain.

In addition, the third wire W3 overlapping with the third channel pattern 241 and the third source/drain patterns 251 disposed on opposite sides of the third wire W3 may configure the first pull-up transistor PU1 of FIG. 2. Similarly, the second wire W2 overlapping with the third channel pattern 241 and the third source/drain patterns 251 disposed on opposite sides of the second wire W2 may configure the second pull-up transistor PU2 of FIG. 2. The fourth wire W4 overlapping with the third channel pattern 241 and the third source/drain patterns 251 disposed on opposite sides of the fourth wire W4 may configure the second pass transistor PA2 of FIG. 2.

In addition, the fifth wire W5 overlapping with the third channel pattern 241 and the third source/drain patterns 251 disposed on opposite sides of the fifth wire W5 may configure the first pull-down transistor PD1 of FIG. 2. In addition, the sixth wire W6 overlapping with the third channel pattern 241 and the third source/drain patterns 251 disposed on opposite sides of the sixth wire W6 may configure the second pull-down transistor PD2 transistor of FIG. 2.

Referring to FIG. 11, in the present embodiment, the bit line BL, the driving voltage line VDD, the complementary bit line BL, the ground voltage line VSS, the connection lines CL1, CL2 and CL3, the connection electrode CE, and the via VIA may be disposed on the third source/drain pattern 251. That is, the third source/drain pattern 251 may be connected to a wire at an upper portion of the second layer 2000.

As shown in FIG. 11, the gate structure 260 may surround the third channel pattern 241 and include the gate electrode 265 and the gate insulating layer 262. For example, the gate structure 260 may include a main gate structure 260M and a sub-gate structure 260S. The main gate structure 260M may include a main gate electrode 265M and a main gate insulating film 262M, and the sub-gate structure 260S may include a sub-gate electrode 265S and a sub-gate insulating film 262S.

As may be seen in FIG. 11, an intermediate capping layer 266 may be disposed on the main gate electrode 265M. The connection electrode CE may be disposed through the intermediate capping layer 266. The connection electrode CE may be in direct contact with the gate electrode 265. In addition, the connection electrode CE may be in contact with the third source/drain pattern 251. That is, the connection electrode CE may connect the third source/drain pattern 251 and the gate electrode 265.

In addition, referring to FIG. 11, the third source/drain pattern 251 may be connected to the complementary bit line BLC through the via VIA. According to some embodiments in FIG. 11, other wires may also be connected to the third source/drain pattern 251 through the via VIA.

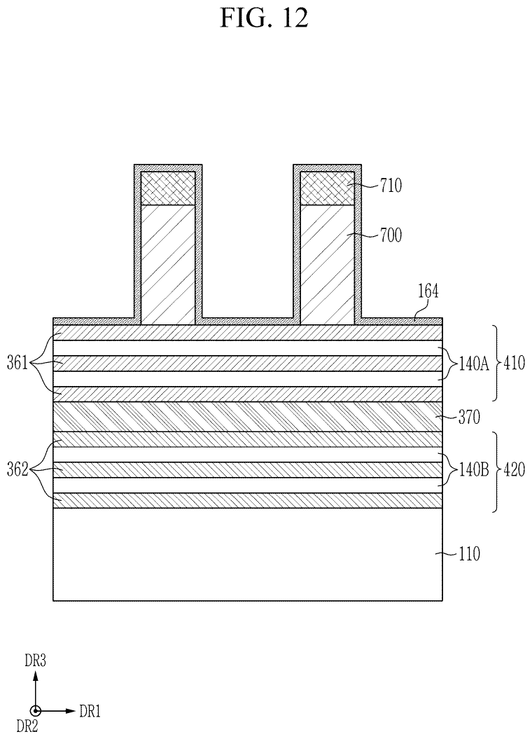

Hereinafter, a method of manufacturing a semiconductor device according to an embodiment will be described with reference to FIG. 12 to FIG. 58. FIG. 12 to FIG. 58 illustrate cross-sectional views of a manufacturing process of a semiconductor device according to an embodiment. However, the manufacturing method described below is only an example, and embodiments of the present disclosure are not limited thereto. In FIG. 12 to FIG. 58, some components are simply shown or omitted for better comprehension and ease of description. That is, the drawings of the present manufacturing method are mostly identical to FIG. 4, but for better comprehension and ease of description, some components may be omitted or formation positions may be slightly different.

Referring to FIG. 12, a second laminate 420 may be formed by alternately stacking second sacrificial layers 362 and second channel patterns 140B on a substrate 110, and a first laminate 410 may be formed by alternately stacking first sacrificial layers 361 and first channel patterns 140A. The substrate 110 may include silicon.

The first channel pattern 140A and the second channel pattern 140B may include silicon (Si) or germanium (Ge). In addition, the plurality of first channel patterns 140A and the plurality of second channel patterns 140B may include a compound semiconductor such as, for example, a group IV-IV compound semiconductor or a group III-V compound semiconductor. The group IV-IV compound semiconductor may be, for example, a binary compound or a ternary compound including at least two or more from among carbon (C), silicon (Si), germanium (Ge), and tin (Sn).

The III-V group compound semiconductor may be, for example, a binary compound, a ternary compound, or a quaternary compound formed by combining at least one from among aluminum (Al), gallium (Ga), and indium (In) as group III elements with one of phosphorus (P), arsenic (As), and antimonium (Sb) as group V elements.

In the embodiment, the first channel pattern 140A and the second channel pattern 140B may include silicon (Si). As another example, the first channel pattern 140A and the second channel pattern 140B may include silicon germanium (SiGe).

The first sacrificial layer 361 and the second sacrificial layer 362 may include silicon germanium (SiGe).

An intermediate layer 370 may be formed between the first laminate 410 and the second laminate 420. The intermediate layer 370 may include silicon germanium (SiGe), and in this case, the intermediate layer 370 may include silicon germanium having a higher germanium concentration than germanium concentrations of the first sacrificial layer 361 and the second sacrificial layer 362. By making the germanium contents of the intermediate layer 370, the first sacrificial layer 361, and the second sacrificial layer 362 different in this way, the intermediate layer 370, the first sacrificial layer 361, and the second sacrificial layer 362 may have an etching selectivity. Therefore, as will be described separately later, only the intermediate layer 370 may be selectively etched in the manufacturing process.

Referring to FIG. 12, a first mask layer 700, a second mask layer 710, and a gate spacer 164 may be formed on the first laminate 410 and the second laminate 420. The first mask layer 700 may be formed to extend in the third direction DR3 perpendicular to the first laminate 410 and the second laminate 420, and may include polycrystalline silicon. The second mask layer 710 may be disposed on the upper portion of the first mask layer 700 and may include an insulating material, and may include SiN, for example. The gate spacer 164 may be formed to cover the upper surface and the side surface of the first mask layer 700 and the second mask layer 710, and the upper surface of the first laminate 410. The gate spacer 164 may include an insulating material.

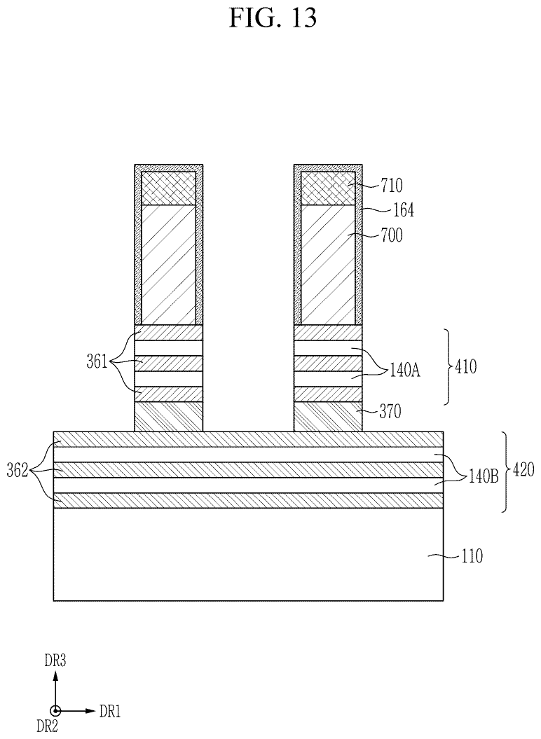

Next, referring to FIG. 13, the first laminate 410 and the intermediate layer 370 may be etched using the first mask layer 700 and the second mask layer 710 as masks.

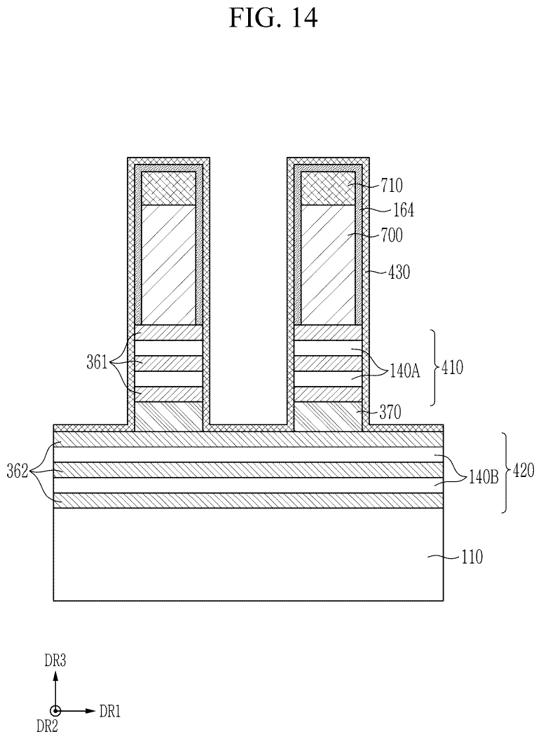

Next, referring to FIG. 14, a separation insulating film 430 may be formed on the upper surface of the etched structure of FIG. 13. The separation insulating film 430 may be formed on the entire surface of the etched structure in the previous step. The separation insulating film 430 may include an insulating material. The separation insulating film 430 may cover the side surfaces of the first mask layer 700, the second mask layer 710, and the first laminate 410, and the upper surfaces of the second laminate 420. The side surface of the first laminate 410 may be covered by the separation insulating film 430 and thus may not be exposed.

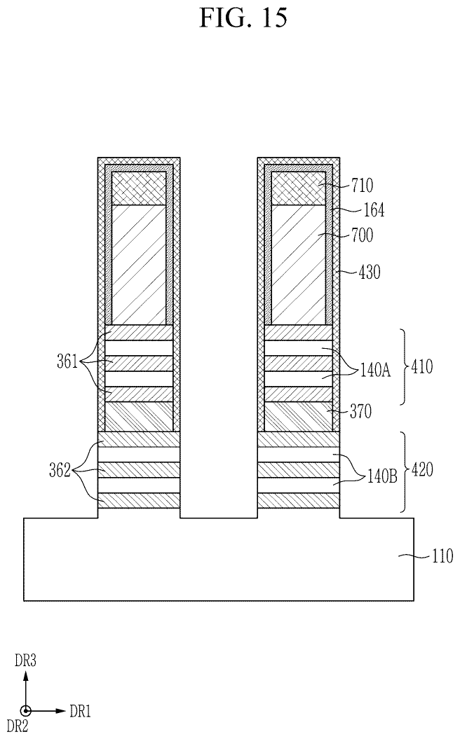

Next, referring to FIG. 15, the second laminate 420 may be etched. In this case, the first laminate 410 may be etched using the first mask layer 700 and the second mask layer 710 as masks. As shown in FIG. 15, portions of the first laminate 410 and the second laminate 420 that do not overlap with the first mask layer 700 may be removed to form an empty space. In FIG. 15, the side surface of the second laminate 420 may not be covered with the separation insulating film 430, and the side surfaces of the second channel pattern 140B and the second sacrificial layer 362 may be exposed.

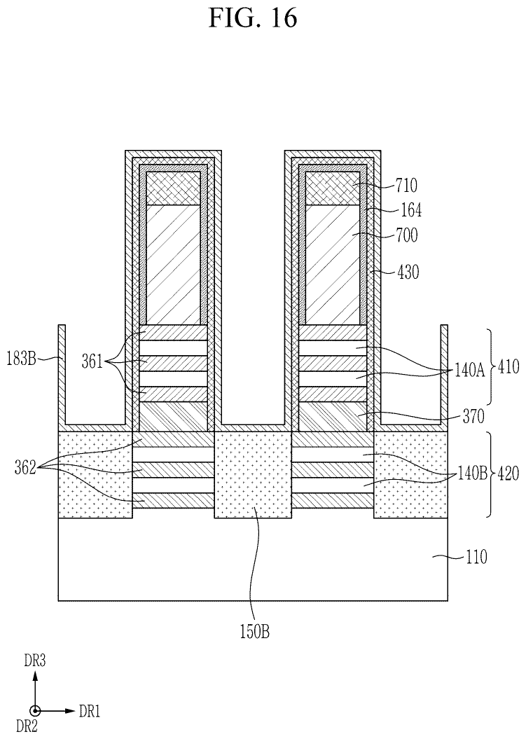

Next, referring to FIG. 16, the second source/drain patterns 150B may be formed in a space between portions of the second laminate 420. The second source/drain pattern 150B may be an epitaxial pattern formed by a selective epitaxial growth process using the plurality of second channel patterns 140B as seeds. The second source/drain patterns 150B may serve as a source/drain of a second transistor structure that uses the plurality of second channel patterns 140B as channel regions.

The second source/drain pattern 150B may include a semiconductor material. The second source/drain pattern 150B may include, for example, silicon (Si) or germanium (Ge). In addition, the second source/drain pattern 150B may include, for example, a binary compound or a ternary compound containing two or more from among carbon (C), silicon (Si), germanium (Ge), and tin (Sn). For example, the second source/drain pattern 150B may include silicon (Si), silicon-germanium (SiGe), germanium (Ge), silicon carbide (SiC), and the like, but is not limited thereto. In the embodiment, the second source/drain pattern 150B is illustrated as being formed of a single layer, but embodiments of the present disclosure are not limited thereto, and the second source/drain pattern 150B may be formed of two or more layers. When the second source/drain pattern 150B includes two or more layers, the concentrations of silicon (Si) or germanium (Ge) included in respective layers may be different.

In the embodiment, the second source/drain pattern 150B may be doped with impurities. For example, when the second transistor structure is an N-type MOSFET, the second source/drain pattern 150B may include an N-type impurity. For example, the second source/drain pattern 150B may include phosphorus (P), antimony (Sb), arsenic (As), or a combination thereof.

In addition, referring to FIG. 16, a second barrier pattern 183B may be formed on the front side of the structure. The second barrier pattern 183B may be formed along the upper surface of the second source/drain patterns 150B and the upper surface of the separation insulating film 430.

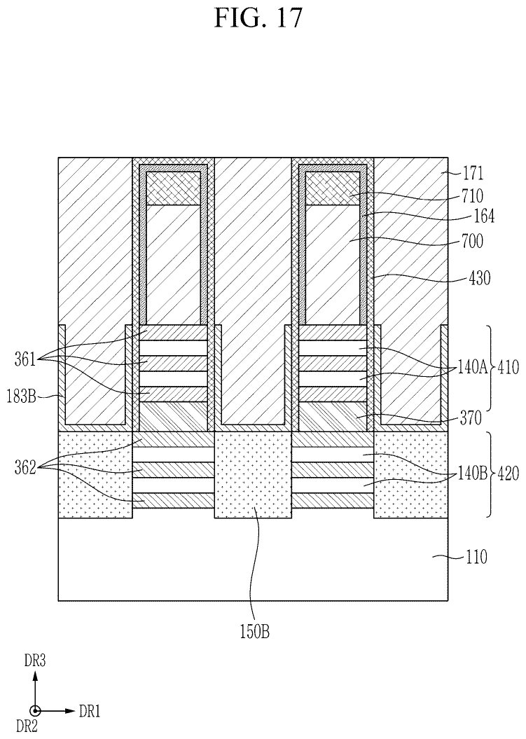

Next, referring to FIG. 17, a second interlayer insulating layer 171 may be formed in a space between portions of the first laminate 410. The second interlayer insulating layer 171 may be formed to fill all spaces between portions of the first laminate 410 and between portions of the first mask layer 700 and portions of the second mask layer 710.

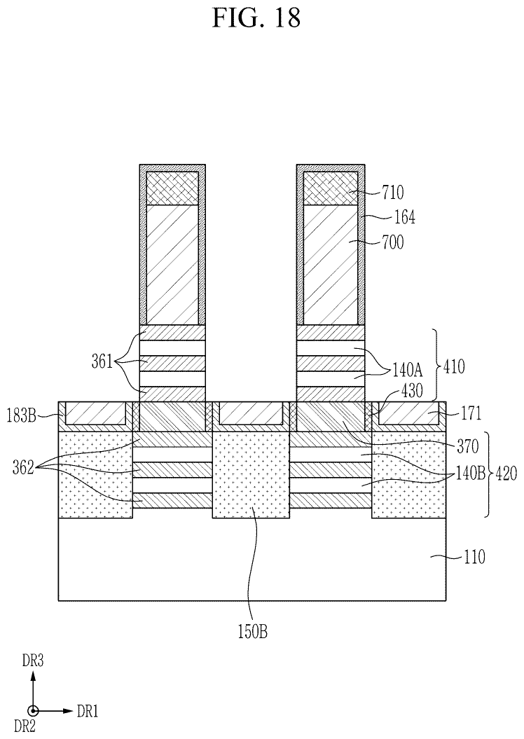

Next, referring to FIG. 18, portions of the second interlayer insulating layer 171 disposed in the spaces between the portions of the first laminate 410 and between portions of the first mask layer 700 and portions of the second mask layer 710 may be removed. Therefore, in the present step, the second interlayer insulating layer 171 may be disposed adjacent to the intermediate layer 370 and may not be adjacent to the first laminate 410. As shown in FIG. 18, the upper surface of the second interlayer insulating layer 171 may be disposed on the same plane as the upper surface of the intermediate layer 370. In addition, in the present step, the separation insulating film 430 covering the first mask layer 700, the second mask layer 710, and the first laminate 410 may be removed. Therefore, as shown in FIG. 18, the side surface of the first laminate 410 may be exposed in the present step. Specifically, the side surfaces of the plurality of first channel patterns 140A included in the first laminate 410 may be exposed.

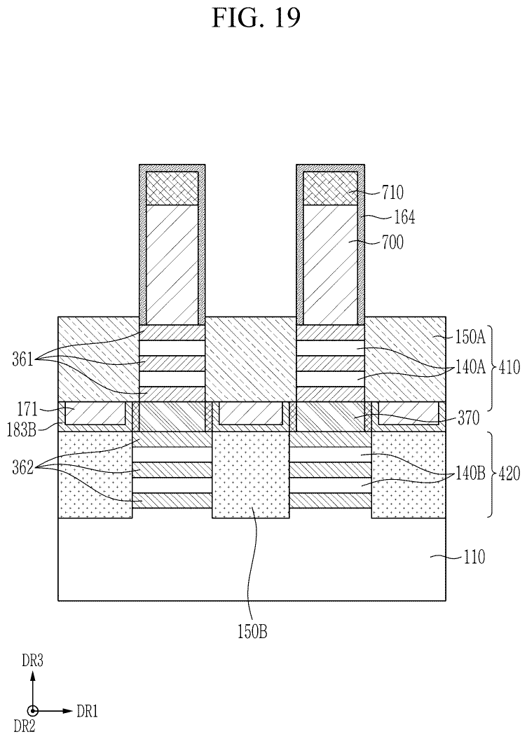

Next, referring to FIG. 19, first source/drain pattern 150A may be formed in spaces between portions of the first laminate 410. The first source/drain pattern 150A may be epitaxial patterns formed by a selective epitaxial growth process using the plurality of first channel patterns 140A as seeds. The first source/drain patterns 150A may serve as a source/drain of a first transistor structure that uses the plurality of first channel patterns 140A as channel regions.

The first source/drain pattern 150A may include a semiconductor material. The first source/drain pattern 150A may include, for example, silicon (Si) or germanium (Ge). In addition, the first source/drain pattern 150A may include, for example, a binary compound or a ternary compound containing two or more of carbon (C), silicon (Si), germanium (Ge), and tin (Sn). For example, the first source/drain pattern 150A may include silicon (Si), silicon-germanium (SiGe), germanium (Ge), silicon carbide (SiC), and the like, but is not limited thereto. In the embodiment, the first source/drain pattern 150A is illustrated as being formed of a single layer, but embodiments of the present disclosure are not limited thereto, and the first source/drain pattern 150A may be formed of two or more layers.

In the embodiment, the first source/drain pattern 150A may be doped with impurities. For example, when the first transistor structure is a P-type MOSFET, the first source/drain pattern 150A may include a P-type impurity. For example, the first source/drain pattern 150A may include boron (B), aluminum (Al), gallium (Ga), or a combination thereof.

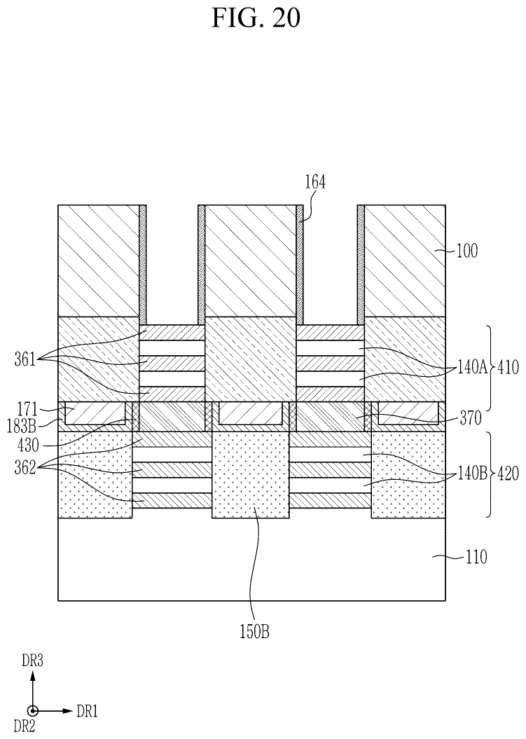

Next, referring to FIG. 20, a first interlayer insulating layer 100 may be formed in a space between the portions of the first mask layer 700 and the portions of the second mask layer 710. The first interlayer insulating layer 100 may include an oxide, a nitride, an oxynitride, or a combination thereof. For example, the first interlayer insulating layer 100 may include a silicon oxide (SiO₂). Next, the first mask layer 700 and the second mask layer 710 may be removed. Thereafter, the gate spacer 164 may also be partially removed through a chemical mechanical planarization (CMP) process or the like.

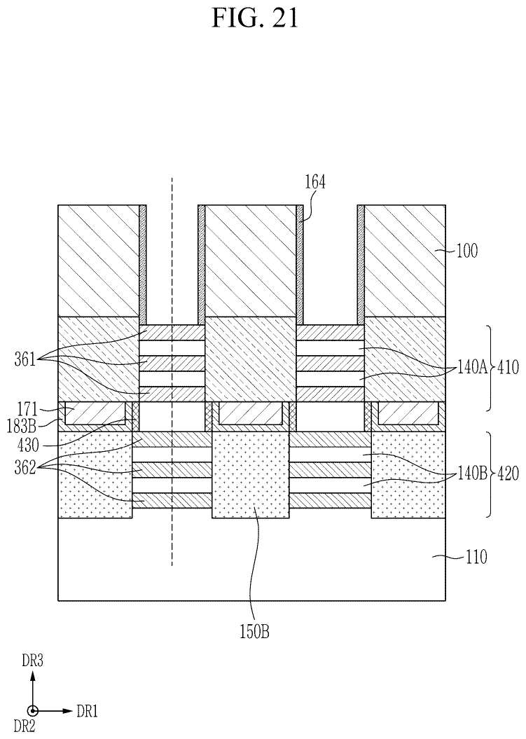

Referring to FIG. 21, the intermediate layer 370 may be removed. In this case, as described above, the intermediate layer 370 may have etch selectivity with respect to the first sacrificial layer 361 and the second sacrificial layer 362, so only the intermediate layer 370 may be removed without removing the first sacrificial layer 361 and the second sacrificial layer 362.

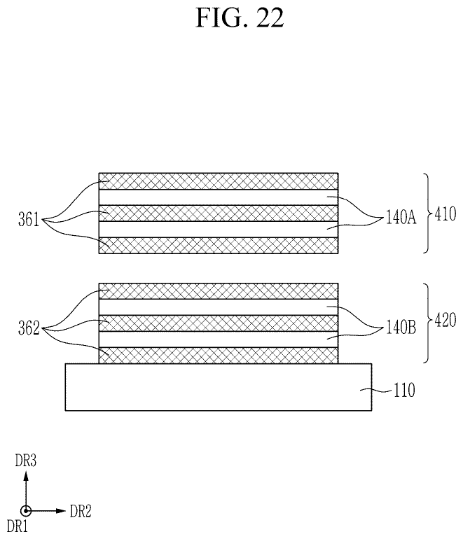

FIG. 22 illustrates a cross-sectional view along a dotted line in FIG. 21. That is, FIG. 22 illustrates a cross section in the second direction DR2 for better comprehension and ease of description. Referring to FIG. 22, the intermediate layer 370 may be removed to form an empty space between the first laminate 410 and the second laminate 420.

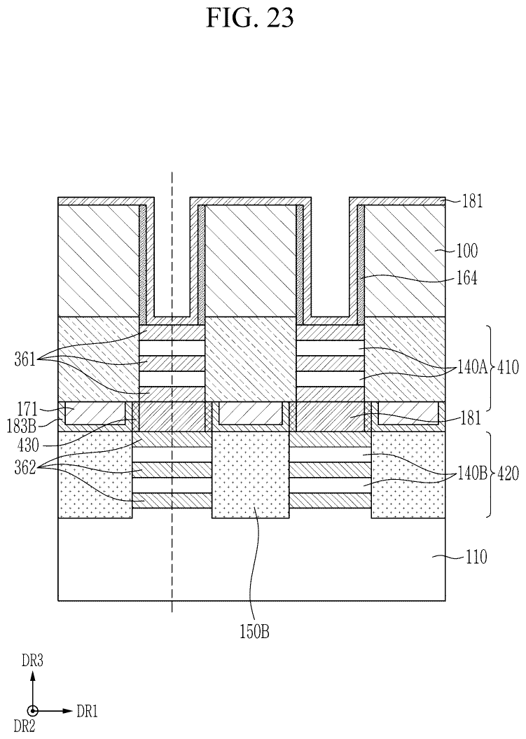

Next, referring to FIG. 23, an intermediate insulating pattern 181 may be formed in a region where the intermediate layer 370 is removed. The intermediate insulating pattern 181 may be disposed in a space from which the intermediate layer 370 is removed, and may be disposed to cover the side surfaces of the etched first laminate 410 and second laminate 420.

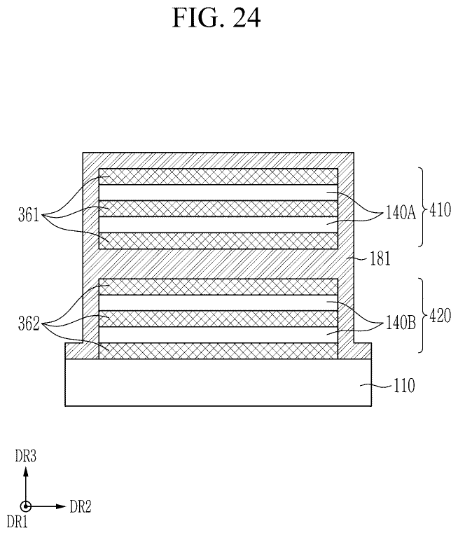

FIG. 24 illustrates a cross-sectional view along a dotted line in FIG. 23. Hereinafter, for better comprehension and ease of description, FIG. 24 to FIG. 28 illustrate cross sections in the second direction DR2. Referring to FIG. 24, in the present step, the side surfaces of the first laminate 410 and the second laminate 420 may be covered with the intermediate insulating pattern 181.

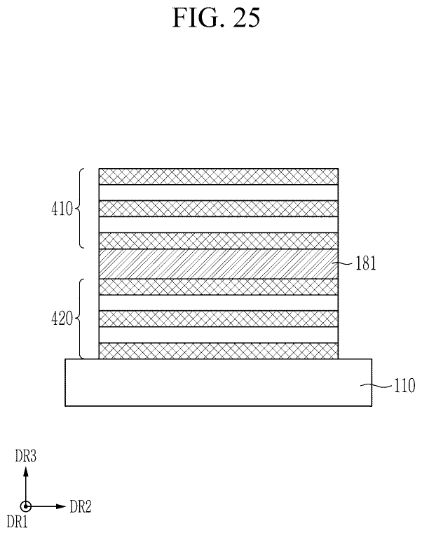

Next, referring to FIG. 25, portions of the intermediate insulating pattern 181 surrounding the side surfaces of the first laminate 410 and the second laminate 420 may be removed. Therefore, in the present step, the side surfaces of the first laminate 410 and the second laminate 420 in the second direction DR2 may be exposed.

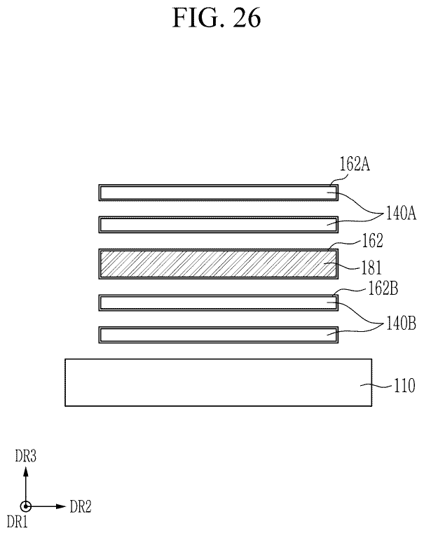

Next, referring to FIG. 26, the first sacrificial layer 361 and the second sacrificial layer 362 may be removed. As shown in FIG. 25, the side surfaces of the first laminate 410 and the second laminate 420 in the second direction DR2 may be exposed, so the etching solution may be introduced into the corresponding portion to remove the first sacrificial layer 361 and the second sacrificial layer 362. After the first sacrificial layer 361 and the second sacrificial layer 362 are removed, a gate insulating film 162 may be formed. The first gate insulating film 162A may be formed along the circumference of each of the plurality of first channel patterns 140A, and the second gate insulating film 162B may be formed along the circumference of each of the plurality of second channel patterns 140B.

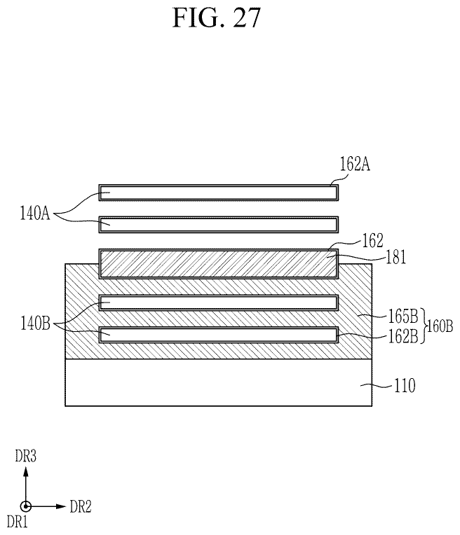

Next, referring to FIG. 27, a second gate electrode 165B may be formed in a region from which the second sacrificial layer 362 is removed. The second gate electrode 165B may include a conductive material. The second gate electrode 165B may include at least one from among a metal, a metal alloy, a conductive metal nitride, a metal silicide, a doped semiconductor material, a conductive metal oxide, and a conductive metal nitride. The second gate electrode 165B and the second gate insulating film 162B may configure the second gate structure 160B.

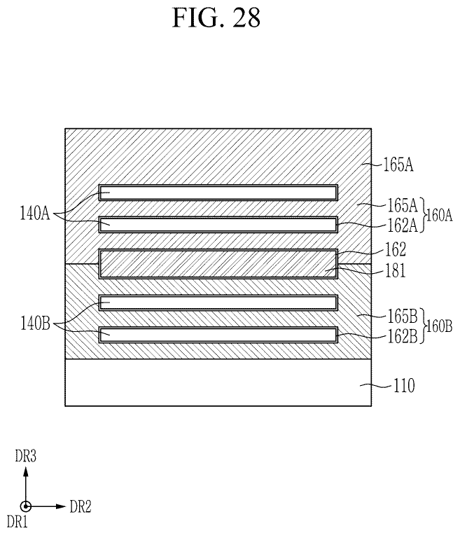

Next, referring to FIG. 28, a first gate electrode 165A may be formed in a region from which the first sacrificial layer 361 is removed. The first gate electrode 165A may include a conductive material. The first gate electrode 165A may include at least one from among a metal, a metal alloy, a conductive metal nitride, a metal silicide, a doped semiconductor material, a conductive metal oxide, and a conductive metal nitride. The first gate electrode 165A and the first gate insulating film 162A may configure the first gate structure 160A.

The first gate electrode 165A and the second gate electrode 165B may include the same material as each other or may include different materials from each other. The first gate electrode 165A and the second gate electrode 165B may have different conductivity types from each other.

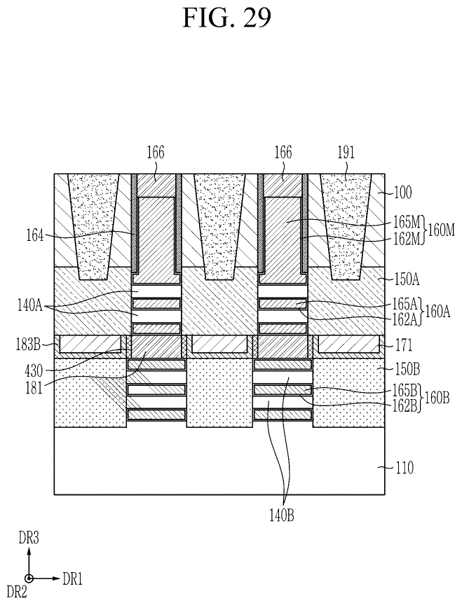

Referring back to FIG. 29, which is a cross-sectional view in the first direction DR1, the first gate electrode 165A may be formed up to a space between the first interlayer insulating layer 100. The upper surface of the first gate electrode 165A may configure the main gate electrode 165M. That is, in the cross-sectional view of FIG. 29, the main gate electrode 165M and the main gate insulating film 162M may configure the main gate electrode 165M. The main gate structure 160M may be disposed on the first gate structure 160A. A capping layer 166 may be disposed on the main gate electrode 165M.

In addition, referring to FIG. 29, a first contact electrode 191 penetrating the first interlayer insulating layer 100 may be formed. The first contact electrode 191 may be electrically connected to the first source/drain pattern 150A. The first contact electrode 191 may include at least one from among a metal, a metal alloy, a conductive metal nitride, a conductive metal carbide, a conductive metal oxide, a conductive metal carbonitride, and a two-dimensional (2D) material. The metal may include at least one from among titanium (Ti), tantalum (Ta), tungsten (W), nickel (Ni), cobalt (Co), and platinum (Pt). The conductive metal nitride may include at least one from among a titanium nitride (TiN), a tantalum nitride (TaN), a tungsten nitride (WN), a nickel nitride (NiN), a cobalt nitride (CoN), and a platinum nitride (PtN).

According to some embodiments in the cross-sectional view of FIG. 29, the first contact electrode 191 may be connected to a wire that transmits an electrical signal or power voltage supplied from the outside, and may provide this to the first source/drain pattern 150A.

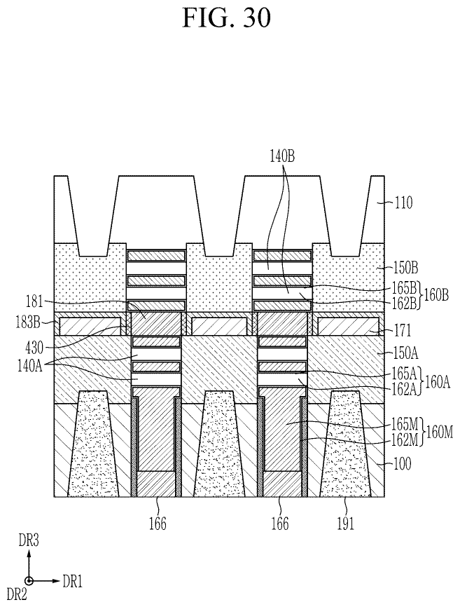

Next, referring to FIG. 30, the structure formed up to the previous step may be flipped. Accordingly, the first interlayer insulating layer 100 may be disposed downward, and the substrate 110 may be disposed on the upper side. Next, the substrate 110 may be etched. In this process, the second source/drain patterns 150B may be exposed.

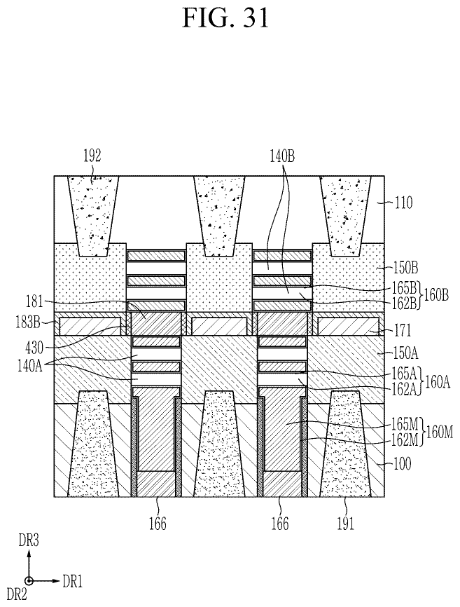

Next, referring to FIG. 31, second contact electrodes 192 may be formed at the position where the substrate 110 is previously etched. The second contact electrodes 192 may be electrically connected to the second source/drain patterns 150B. The second contact electrode 192 may include at least one from among a metal, a metal alloy, a conductive metal nitride, a conductive metal carbide, a conductive metal oxide, a conductive metal carbonitride, and a two-dimensional (2D) material. The metal may include at least one from among titanium (Ti), tantalum (Ta), tungsten (W), nickel (Ni), cobalt (Co), and platinum (Pt). The conductive metal nitride may include at least one from among a titanium nitride (TiN), a tantalum nitride (TaN), a tungsten nitride (WN), a nickel nitride (NiN), a cobalt nitride (CoN), and a platinum nitride (PtN).

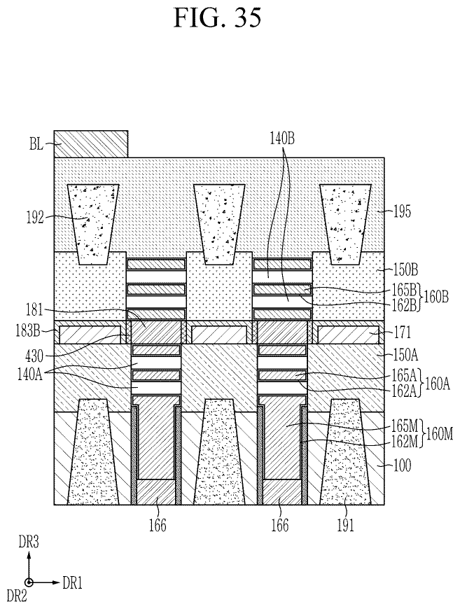

According to some embodiments in the cross-sectional view of FIG. 35, the second contact electrode 192 may be connected to a wire that transmits an electrical signal or power voltage supplied from the outside, and may provide the electrical signal or power voltage to the second source/drain pattern 150B.

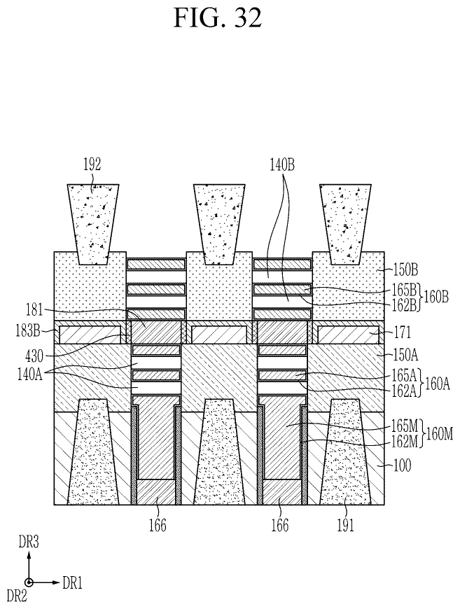

Next, referring to FIG. 32, the substrate 110 may be removed.

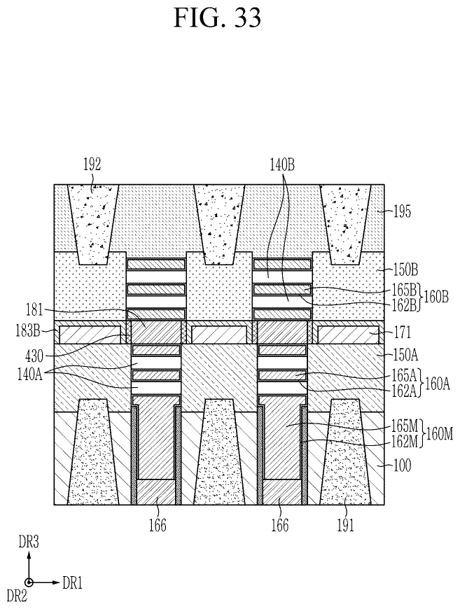

Next, referring to FIG. 33, an upper insulating layer 195 may be formed at a position where the substrate 110 is removed. Although illustrated briefly in FIG. 33, a shape as illustrated in FIG. 33 may be manufactured through a CMP process after the upper insulating layer 195 is formed on an entire surface of the result of FIG. 32.

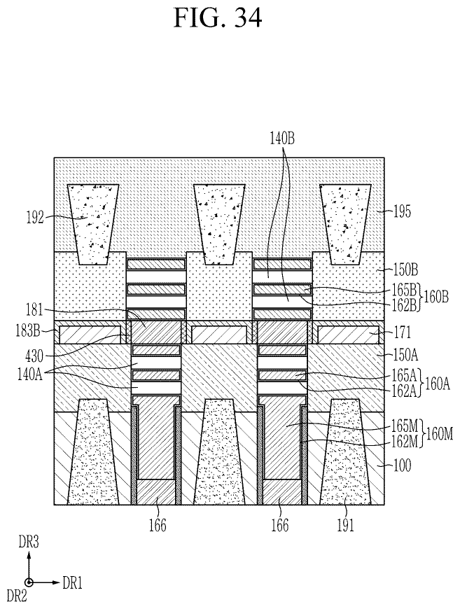

Next, referring to FIG. 34, another portion of the upper insulating layer 195 may be additionally formed on the prior portion of the upper insulating layer 195. Depending on the embodiment, this step may be omitted. Through the present step, the upper surface of the second contact electrode 192 may be covered with the upper insulating layer 195.

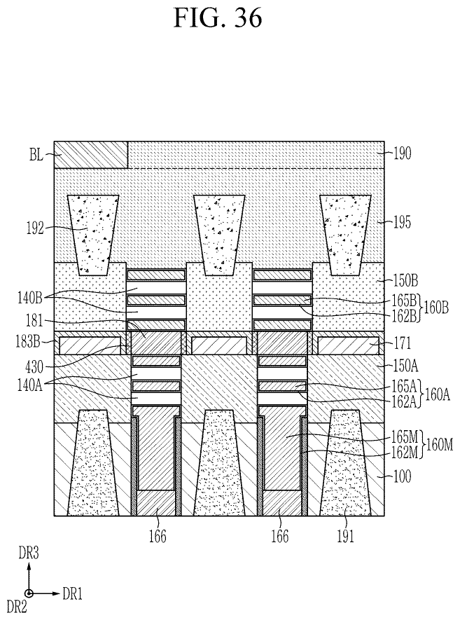

Next, referring to FIG. 35, a wire may be formed. In the cross-sectional view of FIG. 36, the configuration in which the bit line BL is formed is illustrated, but is not limited thereto, and other wires disposed in the same layer as the bit line BL may also be formed in the present step.

Next, referring to FIG. 36, an interlayer insulating layer 190 may be formed on the upper insulating layer 195. In this case, the interlayer insulating layer 190 may not be formed on the bit line BL. Although illustrated briefly in FIG. 36, a shape as illustrated in FIG. 36 may be manufactured through a CMP process after the interlayer insulating layer 190 is formed on an entire surface of the result of FIG. 35. The interlayer insulating layer 190 may include the same material as a material of the upper insulating layer 195. In this case, the boundary between the interlayer insulating layer 190 and the upper insulating layer 195 may not be visually recognized. However, this is an example, and the interlayer insulating layer 190 and the upper insulating layer 195 may include different materials from each other.

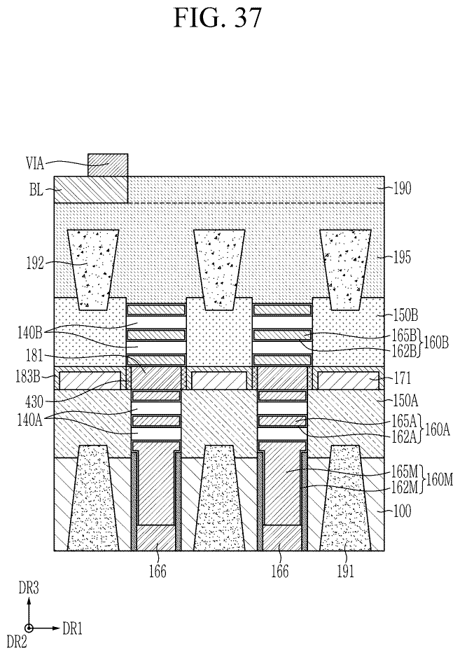

Next, referring to FIG. 37, a via VIA may be formed on the bit line BL. The via VIA may be in contact with the bit line BL.

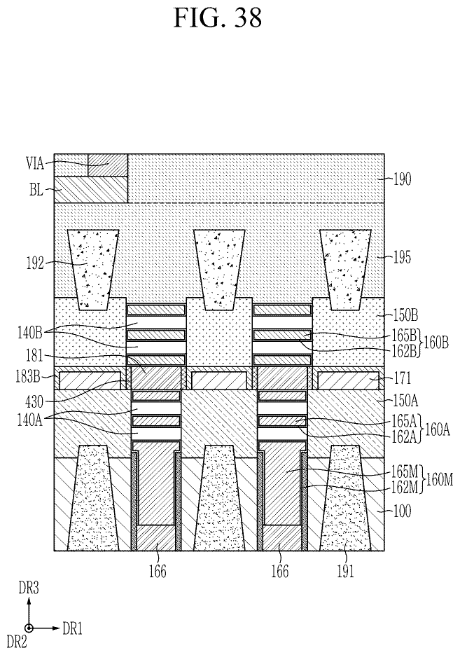

Next, referring to FIG. 38, another portion of the interlayer insulating layer 190 may be formed on the prior portion of the interlayer insulating layer 190. In this case, the interlayer insulating layer 190 may not be formed on the via VIA. Although illustrated briefly in FIG. 38, a shape as illustrated in FIG. 38 may be manufactured through a CMP process after the interlayer insulating layer 190 is formed on an entire surface of the result of FIG. 37.

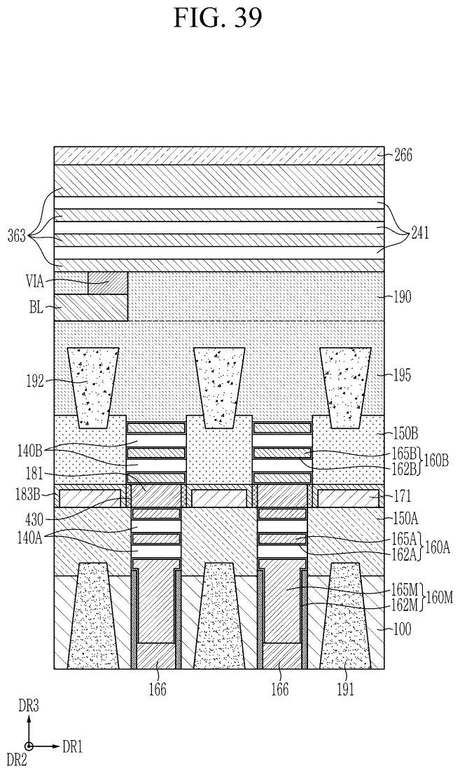

Next, referring to FIG. 39, a laminate of third sacrificial layers 363 and third channel patterns 241 may be formed. An intermediate capping layer 266 may be formed on the upper surface of the laminate.

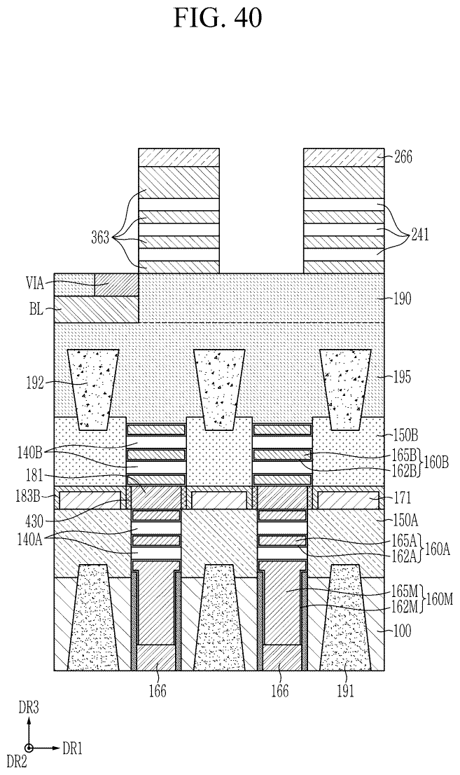

Next, referring to FIG. 40, the laminate of the third sacrificial layers 363 and the third channel patterns 241 may be etched. During this process, the side surfaces of the third sacrificial layers 363 and the third channel patterns 241 may be exposed.

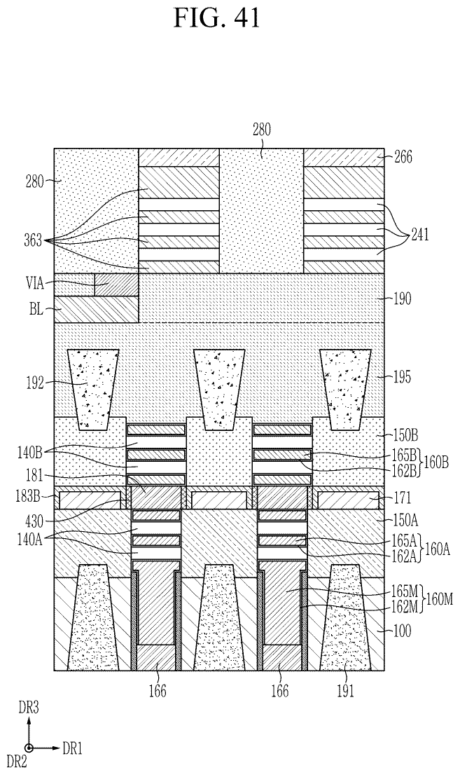

Next, referring to FIG. 41, a dummy layer 280 may be formed in the etched space between portions of the third sacrificial layers 363 and the third channel patterns 241. The dummy layer 280 may include an insulating material. The dummy layer 280 may include a material having etch selectivity with respect to the third sacrificial layers 363.

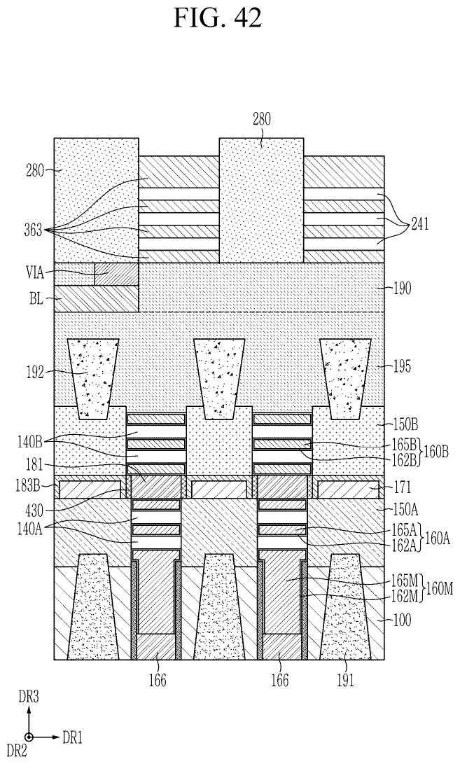

Next, referring to FIG. 42, the intermediate capping layer 266 may be removed.

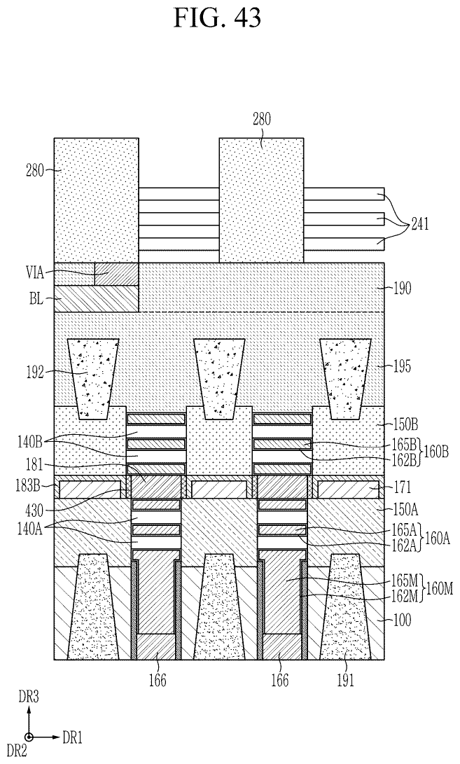

Next, referring to FIG. 43, the third sacrificial layer 363 may be removed. In this case, the third sacrificial layer 363 may have etch selectivity with the dummy layer 280, so the dummy layer 280 may not be removed and the third sacrificial layers 363 may be removed. In the present step, an empty space may be formed between the third channel patterns 241.

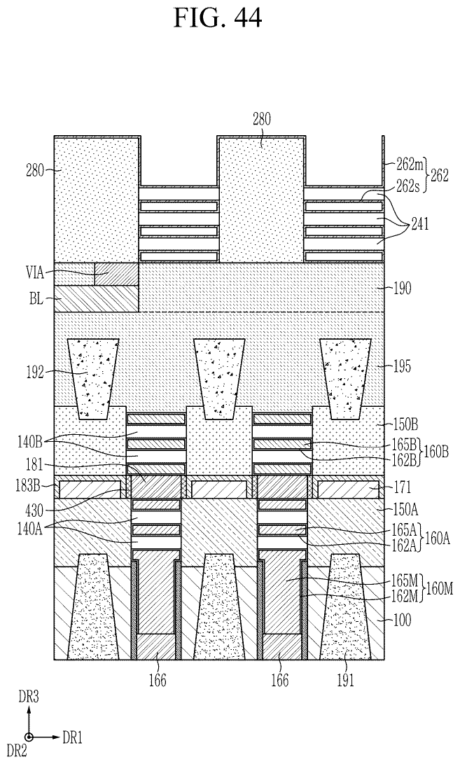

Next, referring to FIG. 44, a gate insulating film 262 may be formed. The gate insulating film 262 may be formed to surround the third channel patterns 241. Referring to FIG. 44, an uppermost portion of the gate insulating film 262 may configure a main gate insulating film 262M, and a portion of the gate insulating film 262 surrounding the third channel patterns 241, other than the uppermost one of the third channel patterns 241, may configure a sub-gate insulating film 262S.

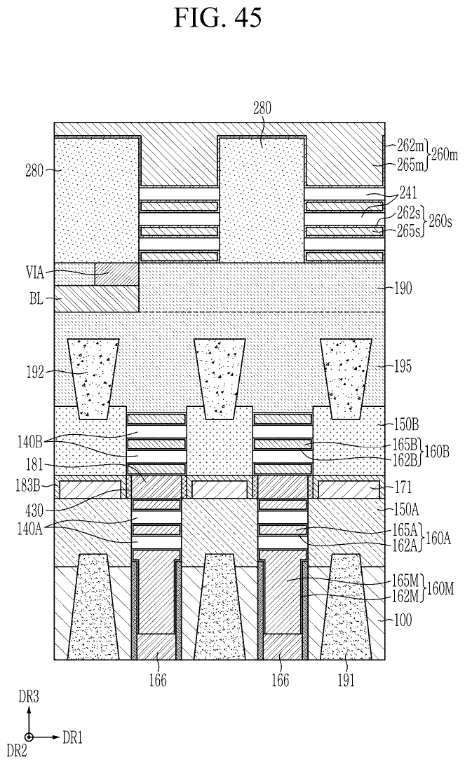

Next, referring to FIG. 45, a gate electrode 265 may be formed. The gate electrode 265 may be formed in a region from which the third sacrificial layers 363 are removed in the previous step. A portion of the gate electrode 265 formed between the third channel patterns 241 in the cross-sectional view of FIG. 45 may configure the sub-gate electrode 265S, and a portion of the gate electrode 265 formed on the third channel patterns 241 may configure the main gate electrode 265M.

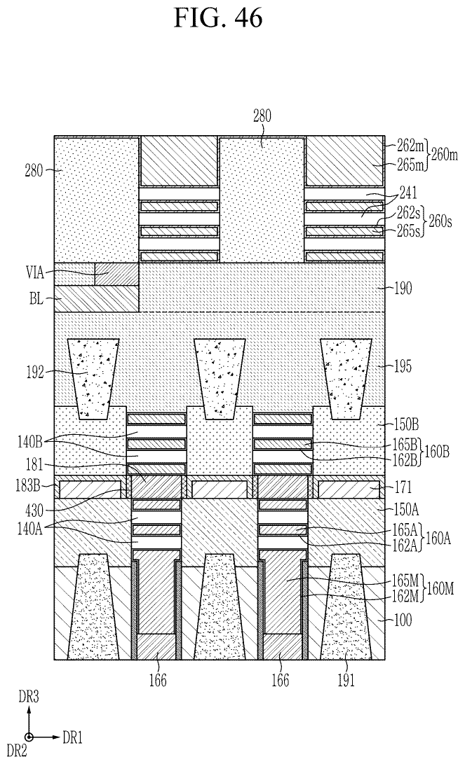

Next, referring to FIG. 46, a portion of the gate electrode 265 overlapping with the dummy layer 280 may be removed. This process may be performed using a CMP process, but is not limited thereto.

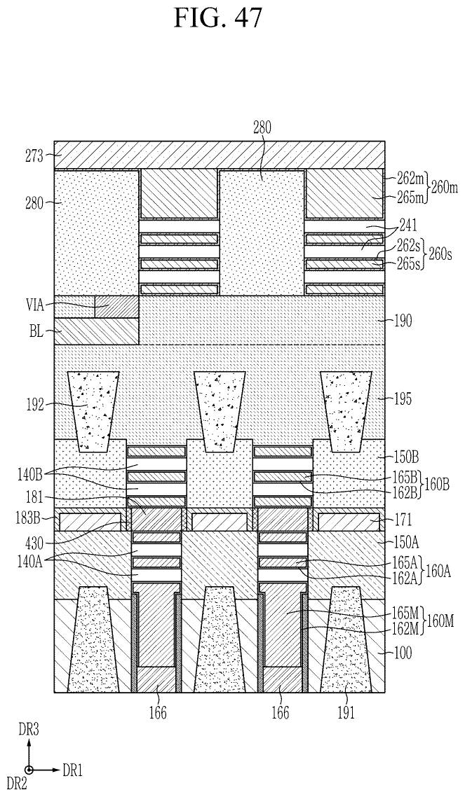

Next, referring to FIG. 47, an interlayer capping layer 273 may be formed.

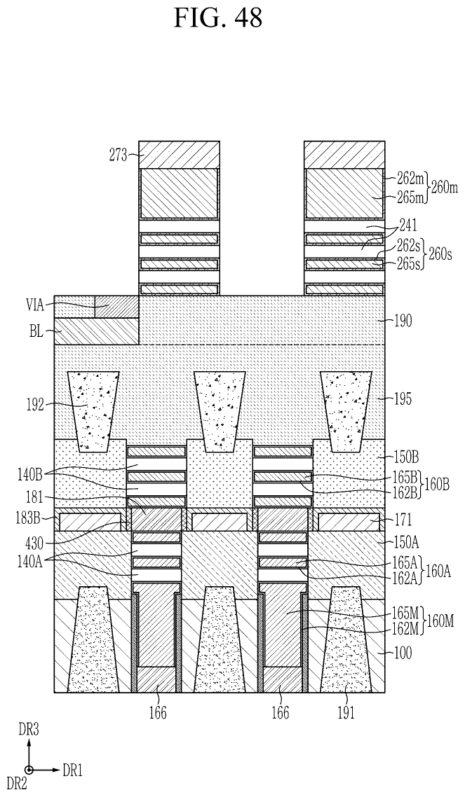

Next, referring to FIG. 48, the dummy layer 280 and portions of the interlayer capping layer 273 overlapping with the dummy layer 280 may be removed.

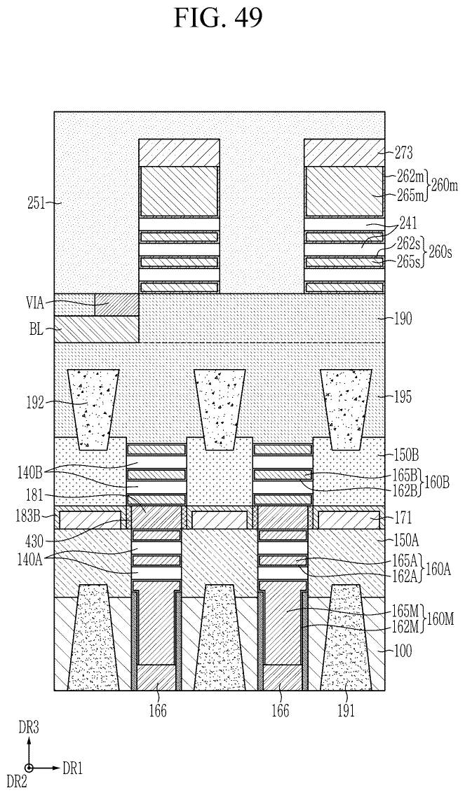

Next, referring to FIG. 49, a third source/drain pattern 251 may be formed in a space from which the dummy layer 280 is removed. The third source/drain pattern 251 may function as the source/drain of each transistor. The third source/drain pattern 251 may include a metal.

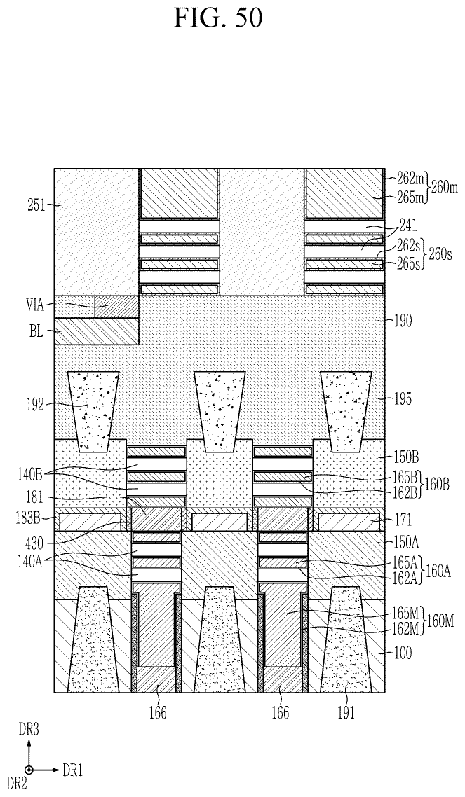

Next, referring to FIG. 50, portions of the third source/drain pattern 251 overlapping with the third channel patterns 241 and the gate structure may be removed. This process may be performed using a CMP process, but is not limited thereto.

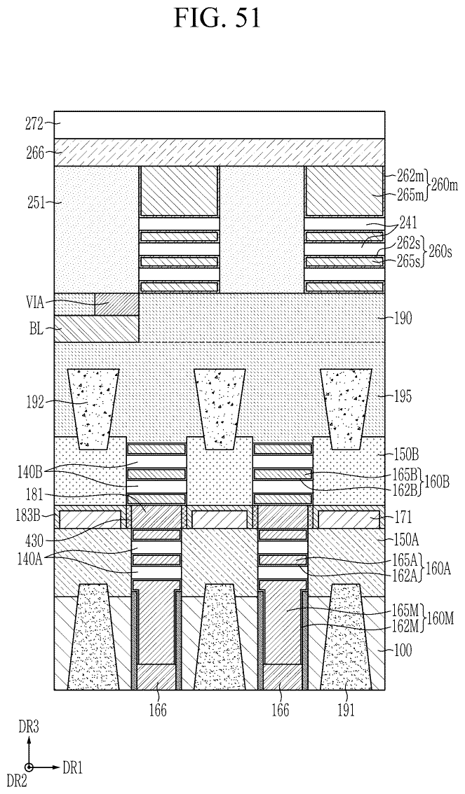

Next, referring to FIG. 51, an intermediate capping layer 266 may be formed. The intermediate capping layer 266 may cap the upper surface of the main gate electrode 265M while being in contact with the upper surface of the main gate electrode 265M. In addition, a second insulating layer (e.g., the second insulating film 272) may be formed on the intermediate capping layer 266.

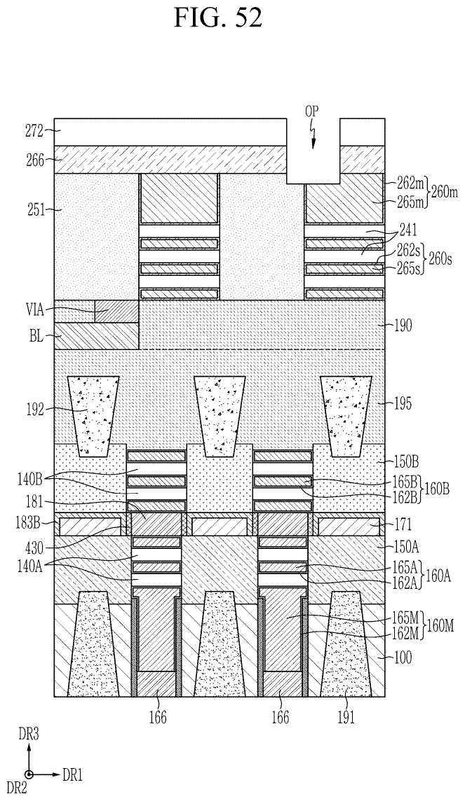

Next, referring to FIG. 52, an opening OP may be formed. In this case, the opening OP may be formed throughout the second insulating film 272, the intermediate capping layer 266, the third source/drain pattern 251, and the main gate electrode 265M.

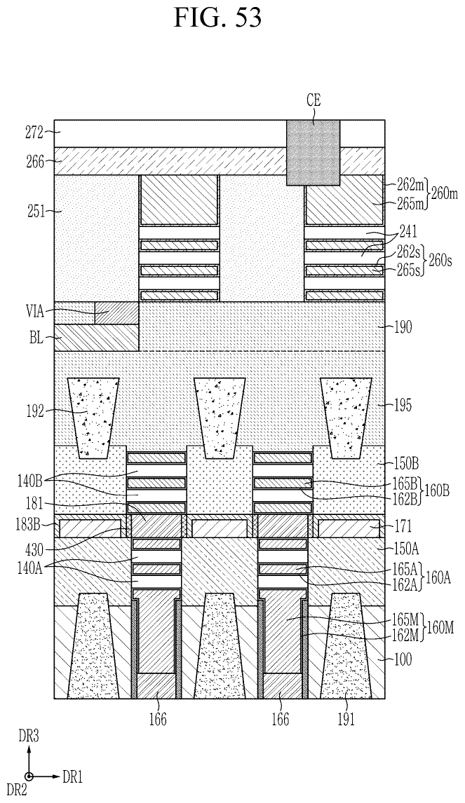

Next, referring to FIG. 53, a connection electrode CE may be formed in the opening OP. Through this process, the third source/drain pattern 251 and the gate electrode (e.g., the main gate electrode 265M) may be connected.

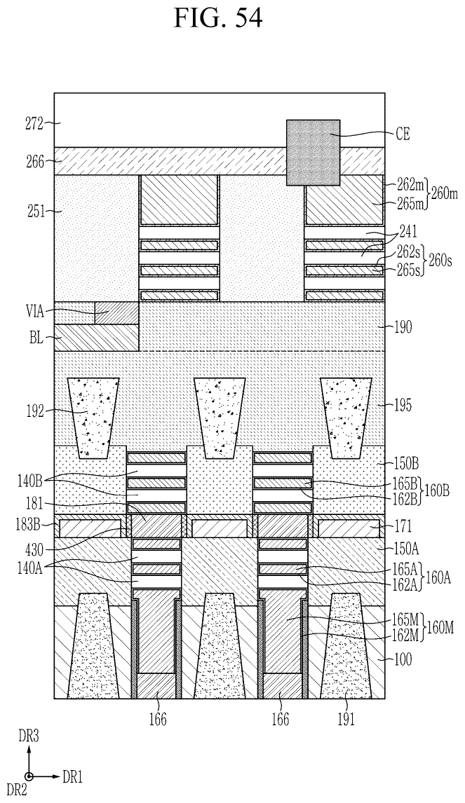

Next, referring to FIG. 54, a second insulating film 272 may be additionally formed to cover the connection electrode CE.

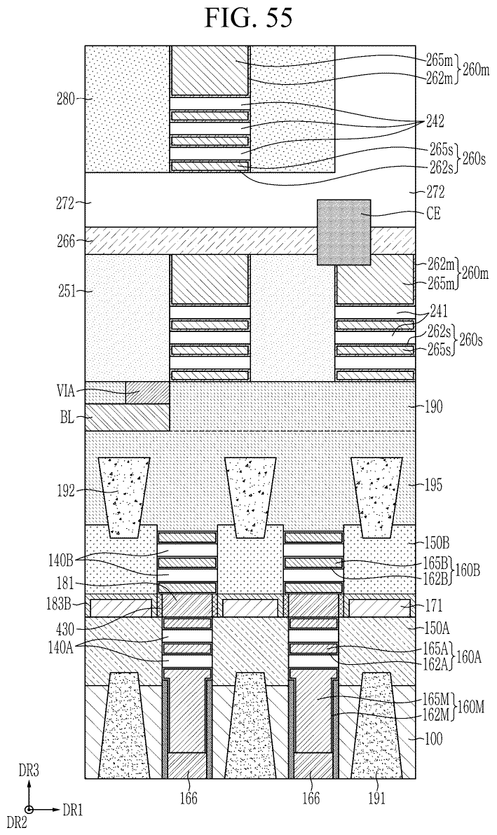

Next, referring to FIG. 55, an additional portion of the second insulating film 272 may be formed on the prior portion of the second insulating film 272, and a dummy layer 280, fourth channel patterns 242, a main gate structure 260M, and a sub-gate structure 260S may be formed using the same process as discussed above. The main gate structure 260M may include a main gate insulating film 262M and a main gate electrode 265M, and the sub-gate structure 260S may include a sub-gate insulating film 262S and a sub-gate electrode 265S.

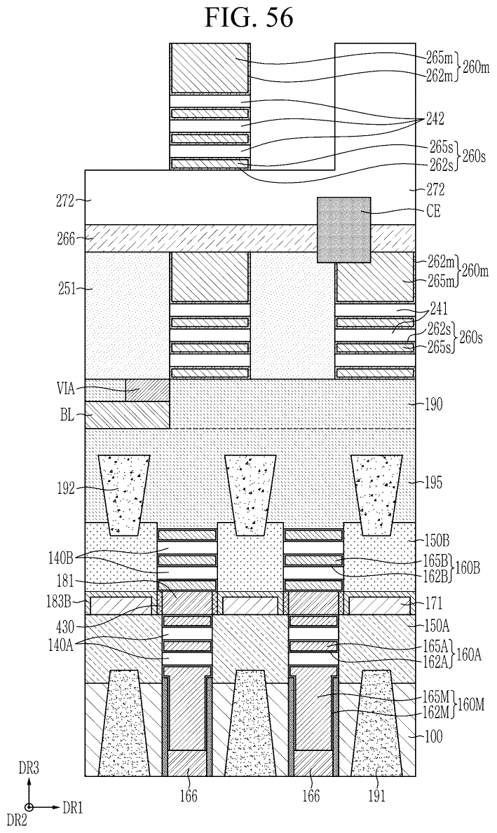

Next, referring to FIG. 56, the dummy layer 280 may be removed.

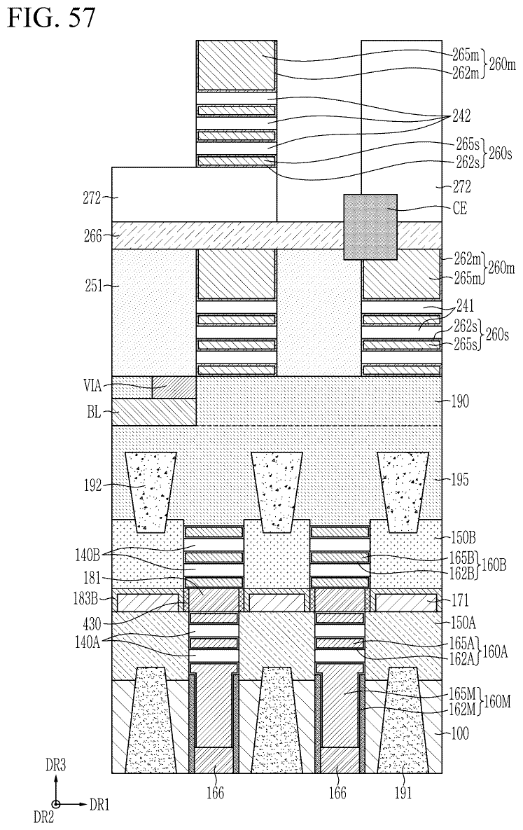

Next, referring to FIG. 57, the second insulating film 272 may be additionally etched to expose the connection electrode CE.

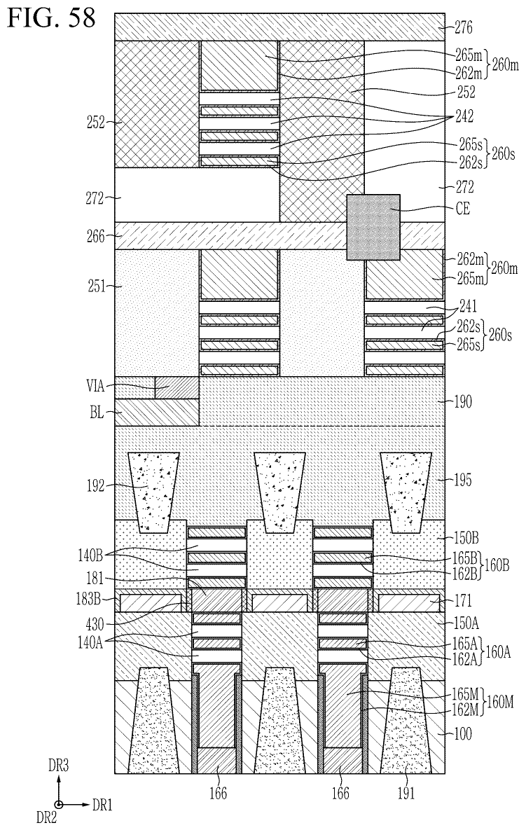

Next, referring to FIG. 58, fourth source/drain patterns 252 may be formed in a region from which the dummy layer 280 is removed and a region from which the second insulating film 272 is further etched. The fourth source/drain patterns 252 may function as the source/drain of each transistor. The fourth source/drain pattern 252 may include a metal.

In this case, the fourth source/drain pattern 252 may be in contact with the connection electrode CE. The connection electrode CE may be in contact with the third source/drain pattern 251, so the third source/drain pattern 251 and the fourth source/drain pattern 252 may be connected through the connection electrode CE.

Next, an upper capping layer 276 may be formed.

However, although the connection form of the connection electrode CE and the fourth source/drain pattern 252 in FIG. 52 and below of the present manufacturing method drawing is partially different from that in FIG. 4, this is illustrated for better comprehension and ease of description, and embodiments of the present disclosure are not limited thereto.

As described above, the semiconductor device according to the present embodiment has a structure in which the first layer 1000 and the second layer 2000 are vertically stacked, the first layer 1000 may include PMOS and NMOS, and the second layer 2000 may include SRAM. By vertically stacking PMOS, NMOS, and SRAM in this way, the area occupied by the semiconductor device may be reduced. In addition, since the SRAM includes IGZO or a two-dimensional material as a channel, a high temperature may not be required during the process, so damage to the first layer 1000 may be prevented during the formation of the second layer 2000.

What is claimed is:

1. A semiconductor device comprising:
a first layer; and
a second layer on the first layer,
wherein the first layer comprises:
a first channel pattern;
a second channel pattern on the first channel pattern;
a first gate structure at least partially surrounding the first channel pattern and the second channel pattern;
first source/drain patterns on opposite sides of the first channel pattern; and
second source/drain patterns on opposite sides of the second channel pattern,
wherein the first source/drain patterns are doped with an impurity of a first conductivity type, and the second source/drain patterns are doped with an impurity of a second conductivity type different from the first conductivity type,
wherein the second layer comprises a static random-access memory (SRAM) device,
wherein a plurality of transistors of the SRAM device are each a p-type metal-oxide-semiconductor (PMOS) transistor or each an n-type metal-oxide-semiconductor (NMOS) transistor, and
wherein a channel of the SRAM device comprises IGZO or a two-dimensional material.

2. The semiconductor device of claim 1, wherein the second layer comprises:
a third channel pattern;
a second gate structure at least partially surrounding the third channel pattern; and
third source/drain patterns on opposite sides of the third channel pattern.

3. The semiconductor device of claim 2, wherein the second layer further comprises:
a fourth channel pattern on the third channel pattern;
a third gate structure at least partially surrounding the fourth channel pattern;
fourth source/drain patterns on opposite sides of the fourth channel pattern, and
wherein at least one of the third source/drain patterns and at least one of the fourth source/drain patterns are connected.

4. The semiconductor device of claim 3, further comprising a wire,
wherein a portion of the wire is connected to the at least one of the fourth source/drain patterns, and the portion of the wire is on an upper surface of the at least one of the fourth source/drain patterns.

5. The semiconductor device of claim 1, further comprising
an interlayer insulating film between the first layer and the second layer; and
a wire, wherein a portion of the wire is connected to a transistor of the second layer, the portion of the wire being within the interlayer insulating film.

6. The semiconductor device of claim 1, wherein
the SRAM device comprises a first pull-up transistor, a first pull-down transistor, a second pull-up transistor, a second pull-down transistor, a first pass transistor, and a second pass transistor, and
a gate electrode of the first pull-up transistor, a gate electrode of the first pull-down transistor, a gate electrode of the second pull-up transistor, and a gate electrode of the second pull-down transistor are connected together.

7. The semiconductor device of claim 6, wherein
the second layer comprises a first portion and a second portion vertically overlapping with the first portion,
the first pass transistor, the second pass transistor, the first pull-up transistor, and the second pull-up transistor are in the first portion, and
the first pull-down transistor and the second pull-down transistor are in the second portion.

8. The semiconductor device of claim 7, wherein the second pull-up transistor overlaps with the first pull-down transistor, and the first pull-up transistor overlaps with the second pull-down transistor.

9. The semiconductor device of claim 6, wherein
the first pull-up transistor, the first pull-down transistor, the second pull-up transistor, the second pull-down transistor, the first pass transistor, and the second pass transistor are disposed in a same layer as each other.

10. The semiconductor device of claim 9, further comprising wires,
wherein at least one wire from among the wires connected to the first pull-up transistor, the first pull-down transistor, the second pull-up transistor, the second pull-down transistor, the first pass transistor, and the second pass transistor is below the plurality of transistors, and at least one other wire from among the wires is above the plurality of transistors.

11. The semiconductor device of claim 2, wherein
the first channel pattern and the second channel pattern comprise silicon,
the third channel pattern comprises IGZO, and
the plurality of transistors of the SRAM device are all NMOS transistors.

12. The semiconductor device of claim 1, wherein
the two-dimensional material comprises at least one from among molybdenum disulfide (MoS₂), molybdenum diselenide (MoSe₂), tungsten disulfide (WS₂), tungsten diselenide (WSe₂), and black phosphorus (BP).

13. A semiconductor device comprising:
a first layer; and
a second layer on the first layer,
wherein the first layer comprises:
a first channel pattern;
a second channel pattern on the first channel pattern;
a gate structure at least partially surrounding the first channel pattern and the second channel pattern;
first source/drain patterns on opposite sides of the first channel pattern; and
second source/drain patterns on opposite sides of the second channel pattern,
wherein the first source/drain patterns are doped with an impurity of a first conductivity type, and the second source/drain patterns are doped with an impurity of a second conductivity type different from the first conductivity type,
wherein the second layer comprises a first pull-up transistor, a first pull-down transistor, a second pull-up transistor, a second pull-down transistor, a first pass transistor, and a second pass transistor,
wherein gate electrodes of the first pull-up transistor, the first pull-down transistor, the second pull-up transistor, and the second pull-down transistor are connected together, and
wherein channels of the first pull-up transistor, the first pull-down transistor, the second pull-up transistor, the second pull-down transistor, the first pass transistor, and the second pass transistor comprise IGZO or a two-dimensional material.

14. The semiconductor device of claim 13, wherein
the second layer comprises a first portion and a second portion vertically overlapping with the first portion,
the first pass transistor, the second pass transistor, the first pull-up transistor, and the second pull-up transistor are in the first portion, and
the first pull-down transistor and the second pull-down transistor are in the second portion.

15. The semiconductor device of claim 14, wherein
the second pull-up transistor overlaps with the first pull-down transistor, and
the first pull-up transistor overlaps with the second pull-down transistor.

16. The semiconductor device of claim 13, further comprising
an interlayer insulating film between the first layer and the second layer; and
wires, wherein at least one wire from among the wires connected to the first pull-up transistor, the first pull-down transistor, the second pull-up transistor, the second pull-down transistor, the first pass transistor, and the second pass transistor is within the interlayer insulating film.

17. A semiconductor device comprising:
a first layer; and
a second layer on the first layer,
wherein the first layer comprises
a first channel pattern;
a second channel pattern on the first channel pattern;
a gate structure at least partially surrounding the first channel pattern and the second channel pattern;
first source/drain patterns on opposite sides of the first channel pattern; and
second source/drain patterns on opposite sides of the second channel pattern,
wherein the first source/drain patterns are doped with an impurity of a first conductivity type, and the second source/drain patterns are doped with an impurity of a second conductivity type different from the first conductivity type,
wherein the second layer comprises a first pull-up transistor, a first pull-down transistor, a second pull-up transistor, a second pull-down transistor, a first pass transistor, and a second pass transistor, and
wherein a gate electrode of the first pull-up transistor, a gate electrode of the first pull-down transistor, a gate electrode of the second pull-up transistor, and a gate electrode of the second pull-down transistor are connected together.

18. The semiconductor device of claim 17, wherein
a drain of the first pass transistor, a drain of the first pull-up transistor, and a source of the second pull-down transistor are connected to a storage node.

19. The semiconductor device of claim 17, wherein
a drain of the second pass transistor, a drain of the second pull-up transistor, and a source of the first pull-down transistor are connected to a storage node.

20. The semiconductor device of claim 17, wherein
the first pull-up transistor, the first pull-down transistor, the second pull-up transistor, the second pull-down transistor, the first pass transistor, and the second pass transistor are n-type metal-oxide-semiconductor (NMOS) transistors, and
a channel of the first pull-up transistor, a channel of the first pull-down transistor, a channel of the second pull-up transistor, a channel of the second pull-down transistor, a channel of the first pass transistor, and a channel of the second pass transistor comprise IGZO or a two-dimensional material.
